(19) United States
(12) Patent Application Publication
(10) Pub. No.: US 2013/0313332 A1
(43) Pub. Date: Nov. 28, 2013

(54) TEMPERATURE INFORMATION GENERATION CIRCUIT, OSCILLATOR, ELECTRONIC APPARATUS, TEMPERATURE COMPENSATION SYSTEM, AND TEMPERATURE COMPENSATION METHOD OF ELECTRONIC COMPONENT

(71) Applicant: Seiko Epson Corporation, Tokyo (JP)

(72) Inventors: Kensaku ISOHATA, Kamiina (JP); Katsuyoshi TERASAWA, Shiojiri (JP)

(73) Assignee: Seiko Epson Corporation, Tokyo (JP)

(21) Appl. No.: 13/897,710

(22) Filed: May 20, 2013

(30) Foreign Application Priority Data
May 22, 2012 (JP) 2012-116898

(51) Int. Cl. H03L 1/02; G01K 7/02

(52) U.S. Cl. CPC H03L 1/02; G01K 7/021
USPC 236/1 F; 374/163; 331/70

(57) ABSTRACT

A temperature information generation circuit includes a temperature sensor (a first temperature detection section), a high-sensitivity temperature sensor (one or plural second temperature detection sections) having higher sensitivity than that of the temperature sensor, an output selection circuit, and a control section. The output selection circuit and the control section select a detection signal of the high-sensitivity temperature sensor upon supply of a power supply voltage, and then perform switching so as to select a detection signal of the temperature sensor at a predetermined timing.

### BACKGROUND

1. Technical Field

The invention relates to a temperature information generation circuit, an oscillator, an electronic apparatus, a temperature compensation system, and a temperature compensation method of an electronic component.

2. Related Art

A temperature compensated Crystal oscillator (TCXO) is capable of achieving high frequency stability by canceling a shift (frequency deviation) of the oscillation frequency of a quartz crystal resonator from a desired frequency (a nominal frequency) in a predetermined temperature range, and is therefore widely used for apparatuses and systems requiring a highly accurate timing signal, such as terminals and base stations of cellular phones, or Global Positioning System (GPS) receivers.

As shown in FIG. 20A, the TCXO generally uses an AT-cut quartz crystal resonator having a frequency-temperature characteristic approximated by a cubic function, and the cubic function is different between the individual AT-cut quartz crystal resonators. Therefore, in the final inspection of the TCXO, there is provided a process (a temperature compensation process) of obtaining the relationship between the temperature and the oscillation frequency at four or more points to calculate the coefficients of the cubic function, and then writing them in a memory device incorporated in the TCXO as temperature compensation data. Further, when the TCXO operates, it is arranged that the frequency-temperature characteristic of the oscillation signal output therefrom is approximated to be flat by internally generating a temperature compensation voltage for causing such a frequency variation as shown in FIG. 20B with respect to the temperature variation based on the temperature compensation data.

Incidentally, at the time of startup of the oscillator, since the oscillation IC generates heat, the temperature of the IC rises, the heat is conducted to the quartz crystal resonator, and the temperature of the quartz crystal resonator rises with a slight delay. Therefore, during the period from starting up the oscillator until the temperature of the quartz crystal resonator is stabilized, a difference in temperature is caused between the IC and the quartz crystal resonator. As a result, a difference is caused between the detected temperature of the temperature sensor incorporated in the IC and the temperature of the quartz crystal resonator, and it results that the oscillation frequency of the oscillator transiently has a significant error (dF/F) to the nominal frequency (F) for several seconds at the time of startup of the oscillator as shown in, for example, FIG. 21. Therefore, in an application requiring a highly accurate timing signal such as GPS, there is a problem that it is not achievable to perform arithmetic processing using the oscillation frequency of the oscillator for several seconds after startup until the oscillation frequency is stabilized, and thus, a time loss occurs.

To cope with this problem, in JP-A-2008-252812 (Document 1), there is proposed a method of controlling the first-order component of a cubic function obtained by reversing the cubic function of the frequency-temperature characteristic of the quartz crystal resonator to perform temperature compensation so that the frequency variation of the temperature compensated oscillator decreases as the temperature rises, and thus reducing the period of time from the time of startup of the oscillator until the oscillation frequency is stabilized.

However, according to the method of Document 1, although the period of time from the time of startup of the oscillator until the oscillation frequency is stabilized can be reduced, it is difficult to obtain an oscillation signal with an accurate frequency immediately after startup of the oscillator, and the method may sometimes be not effective depending on applications.

Further, although it is possible to adopt a method of outputting the detection value of the temperature sensor incorporated in the oscillation IC and externally performing the temperature compensation immediately after startup of the oscillator, since the temperature variation at the time of startup is so minute that the sensitivity of the temperature sensor may be insufficient in the case in which the temperature compensation range is wide, and sufficient temperature compensation may not be achieved in some cases.

### SUMMARY

An advantage of some aspects of the invention is to provide a temperature information generation circuit, an oscillator, an electronic apparatus, a temperature compensation system, and a temperature compensation method of an electronic component for making accurate temperature compensation of the electronic component possible immediately after startup.

The invention can be implemented as one of the following forms or application examples.

### Application Example 1

A temperature information generation circuit according to this application example includes a first temperature detection section, one or plural second temperature detection sections having detection sensitivity higher than detection sensitivity of the first temperature detection section, and a selection section adapted to select a detection signal of the one or plural second temperature detection sections upon supply of a power supply voltage, and then selecting a detection signal of the first temperature detection section at a predetermined timing.

According to the temperature information generation circuit related to this application example, since the detection signal of the one or plural second temperature detection sections having high detection sensitivity is output when the power supply voltage is supplied, by monitoring the detection signal, a small temperature variation due to heat generation of an electronic component including the temperature information generation circuit can accurately be captured. Therefore, by using the temperature information generation circuit according to this application example, the accurate temperature compensation of the electronic component can be performed immediately after startup.

Further, according to the temperature information generation circuit related to this application example, since it becomes that the detection signal of the first temperature detection section having lower detection sensitivity than that of the one or plural second temperature detection sections after the predetermined timing after the power supply voltage is supplied, by monitoring the detection signal, the temperature information can be obtained in a wider temperature range.

### Application Example 2

The temperature information generation circuit according to the application example described above may be configured such that the selection section selects the detection signal of the one or plural second temperature detection sections until a predetermined time elapses from the supply of the power supply voltage, and selects the detection signal of the first temperature detection section after the predetermined time has elapsed.

According to the temperature information generation circuit related to this application example, since it can be arranged by appropriately setting the predetermined time that the detection signal of the one or plural second temperature detection sections having higher detection sensitivity is output during a period in which the temperature transiently varies due to heat generation after the power supply voltage is supplied, by monitoring the detection signal, a small temperature variation due to the heat generation of an electronic component including the temperature information generation circuit can accurately be captured.

### Application Example 3

The temperature information generation circuit according to the application example described above may be configured such that the selection section selects the detection signal of the one or plural second temperature detection sections until a variation of the detection signal of the one or plural second temperature detection sections falls within a predetermined range continuously for a predetermined time after the supply of the power supply voltage, and selects the detection signal of the first temperature detection section in a case in which the variation of the detection signal of the one or plural second temperature detection sections falls within the predetermined range continuously for the predetermined time.

After the power supply voltage is supplied, since the temperature transiently varies due to the heat generation, the detection signal of the one or plural second temperature detection sections varies. If the variation becomes within the predetermined range (roughly zero), it is possible to determine that the temperature is stabilized. Therefore, according to the temperature information generation circuit related to this application example, since it can be arranged by appropriately setting the predetermined time that the detection signal of the one or plural second temperature detection sections having higher detection sensitivity is output during a period in which the temperature transiently varies due to heat generation after the power supply voltage is supplied, by monitoring the detection signal, a small temperature variation due to the heat generation of an electronic component including the temperature information generation circuit can accurately be captured.

### Application Example 4

The temperature information generation circuit according to the application example described above may be configured such that the selection section selects the detection signal of the one or plural second temperature detection sections until a variation of a difference between the detection signal of the first temperature detection section and the detection signal of the one or plural second temperature detection sections falls within a predetermined range continuously for a predetermined time after the supply of the power supply voltage, and selects the detection signal of the first temperature detection section in a case in which the variation of the difference between the detection signal of the first temperature detection section and the detection signal of the one or plural second temperature detection sections falls within the predetermined range continuously for the predetermined time.

After the power supply voltage is supplied, since the temperature transiently varies due to the heat generation, the difference between the detection signal of the first temperature detection section and the detection signal of the one or plural second temperature detection sections varies. If the variation becomes within the predetermined range (roughly constant), it is possible to determine that the temperature is stabilized. Therefore, according to the temperature information generation circuit related to this application example, since it can be arranged by appropriately setting the predetermined time that the detection signal of the one or plural second temperature detection sections having higher detection sensitivity is output during a period in which the temperature transiently varies due to heat generation after the power supply voltage is supplied, by monitoring the detection signal, a small temperature variation due to the heat generation of an electronic component including the temperature information generation circuit can accurately be captured.

### Application Example 5

The temperature information generation circuit according to the application example described above may be configured such that the plural second temperature detection sections have respective detectable temperature ranges different from each other.

According to the temperature information generation circuit related to this application example, by using the plurality of second temperature detection sections having the respective detection temperature ranges different from each other, it is possible to cover the detection temperature range of the first temperature detection section.

### Application Example 6

The temperature information generation circuit according to the application example described above may be configured such that the selection section selects one of the detection signals of the plural second temperature detection sections in accordance with the detection signal of the first temperature detection section after supplying the power supply voltage and before selecting the detection signal of the first temperature detection section.

According to the temperature information generation circuit related to this application example, since the temperature can be obtained from the detection signal of the first temperature detection section, by selecting the detection signal of the plural second temperature detection sections having the detection temperature range including the temperature, the accurate temperature compensation can be performed immediately after startup independently of the startup temperature of the electronic component including the temperature information generation circuit.

### Application Example 7

An oscillator according to this application example includes the temperature information generation circuit according to any one of the application examples described above, and an oscillator element.

According to the oscillator related to this application example, since the temperature information generation circuit outputs the detection signal of the one or plural second temperature detection sections having high detection sensitivity after startup and until the temperature of the oscillator element becomes equal to the temperature of the temperature information generation circuit, and is then stabilized, by monitoring the detection signal, the accurate temperature compensation of the electronic component can be performed immediately after startup.

Further, according to the oscillator related to this application example, since the temperature information generation circuit becomes to output the detection signal of the first temperature detection section having lower detection sensitivity than that of the one or plural second temperature detection sections after the temperature of the oscillator element becomes equal to the temperature of the temperature information generation circuit, and is then stabilized, by monitoring the detection signal, the temperature compensation can be performed to a wide range of environmental temperature variation.

### Application Example 8

An electronic apparatus according to this application example includes the temperature information generation circuit according to any one of the application examples described above.

### Application Example 9

A temperature compensation system according to this application example includes an electronic component, and a control device, the electronic component includes a first temperature detection section, and one or plural second temperature detection sections having detection sensitivity higher than detection sensitivity of the first temperature detection section, and the control device performs temperature compensation of the electronic component based on a detection signal of the one or plural second temperature detection sections in a period from when supplying the electronic component with a power supply voltage to a predetermined timing, and performs temperature compensation of the electronic component based on a detection signal of the first temperature detection section after the predetermined timing.

According to the temperature compensation system related to this application example, the control device accurately captures a small temperature variation due to the heat generation of the electronic component using the detection signal of the one or plural second temperature detection sections having higher detection sensitivity after startup of the electronic component until a predetermined timing, and thus, it is possible to perform the accurate temperature compensation of the electronic component immediately after startup.

Further, according to the temperature compensation system related to this application example, the control device can perform the temperature compensation of the electronic component to a wide range of environmental temperature variation using the detection signal of the first temperature detection section after a predetermined timing after startup of the electronic component.

### Application Example 10

A temperature compensation method of an electronic component according to this application example includes: performing, by a control device, temperature compensation of the electronic component based on a detection signal of one or plural second temperature detection sections having detection sensitivity higher than detection sensitivity of a first temperature detection section included in the electronic component in a period from when supplying the electronic component with a power supply voltage to a predetermined timing, and performing, by the control device, the temperature compensation of the electronic component based on a detection signal of the first temperature detection section included in the electronic component after the predetermined timing.

### BRIEF DESCRIPTION OF THE DRAWINGS

The invention will be described with reference to the accompanying drawings, wherein like numbers reference like elements.

FIG. 1 is a diagram showing a configuration example of a frequency temperature compensation system according to a first embodiment of the invention.

FIG. 2 is a diagram showing a configuration example of an oscillator in the first embodiment.

FIG. 3A is a diagram showing an example of the detection sensitivity of a temperature sensor, and FIG. 3B is a diagram showing an example of the detection sensitivity of a high-sensitivity temperature sensor.

FIG. 4A is a diagram showing an example of a flowchart of a process executed by a control section of a control device, and FIG. 4B is a diagram showing an example of a flowchart of a process executed by a control section of an IC of the oscillator.

FIG. 5 is a diagram showing an example of signal waveforms of respective nodes of the oscillator.

FIGS. 6A and 6B are diagrams each showing another configuration example of the frequency temperature compensation system according to the first embodiment.

FIG. 7 is a diagram showing a configuration example of an oscillator in a second embodiment of the invention.

FIG. 8 is a diagram showing an example of a flowchart of a process executed by a control section of an IC of the oscillator in the second embodiment.

FIG. 9 is a diagram showing an example of signal waveforms of respective nodes of the oscillator in the second embodiment.

FIG. 10 is a diagram showing a configuration example of an oscillator in a third embodiment of the invention.

FIG. 11 is a diagram showing an example of a flowchart of a process executed by a control section of an IC of the oscillator in the third embodiment.

FIG. 12 is a diagram showing a configuration example of a frequency temperature compensation system according to a fourth embodiment of the invention.

FIG. 13 is a diagram showing a configuration example of an oscillator in the fourth embodiment.

FIG. 14A is a diagram showing an example of the detection sensitivity of a temperature sensor in the fourth embodiment, and FIG. 14B is a diagram showing an example of the detection sensitivity of a high-sensitivity temperature sensor in the fourth embodiment.

FIG. 15 is a diagram showing an example of a selection logic of a detection signal executed by an output selection circuit in the fourth embodiment.

FIG. 16A is a diagram showing an example of a flowchart of a process executed by a control section of a control device in the fourth embodiment, and FIG. 16B is a diagram showing an example of a flowchart of a process executed by a control section of an IC of the oscillator in the fourth embodiment.

FIG. 17 is a diagram showing an example of signal waveforms of respective nodes of the oscillator in the fourth embodiment.

FIG. 18 is a functional block diagram of an electronic apparatus according to an embodiment of the invention.

FIG. 19 is a diagram showing an example of an appearance of the electronic apparatus according to the embodiment.

FIG. 20A is a diagram showing an example of the frequency-temperature characteristic of a quartz crystal resonator, and FIG. 20B is a diagram showing an example of a frequency variation caused by a temperature compensation voltage.

FIG. 21 is an explanatory diagram of a temperature compensation error caused at the time of startup of the oscillator.

### DESCRIPTION OF EXEMPLARY EMBODIMENTS

Hereinafter, some preferred embodiments of the invention will be described in detail with reference to the accompanying drawings. It should be noted that the embodiments described below do not unreasonably limit the content of the invention as set forth in the appended claims. Further, all of the constituents described below are not necessarily essential elements of the invention.

### 1. Frequency Temperature Compensation System

### 1-1. First Embodiment

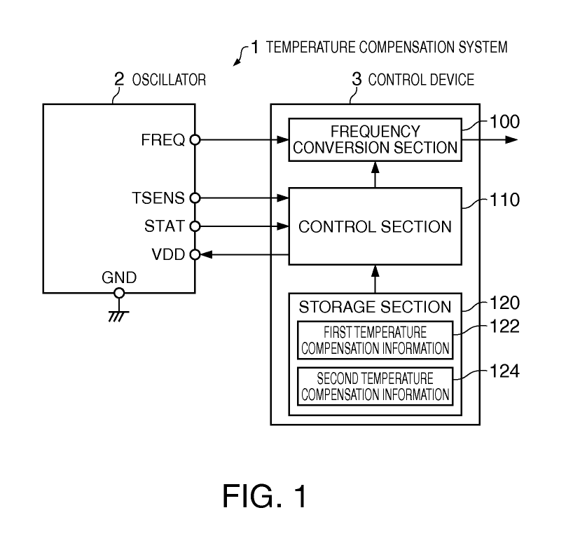

FIG. 1 is a diagram showing a configuration example of a frequency temperature compensation system according to a first embodiment. As shown in FIG. 1, the frequency temperature compensation system according to the first embodiment is configured including an oscillator 2 (an example of an electronic component) and a control device 3, and performs temperature compensation of the oscillator 2.

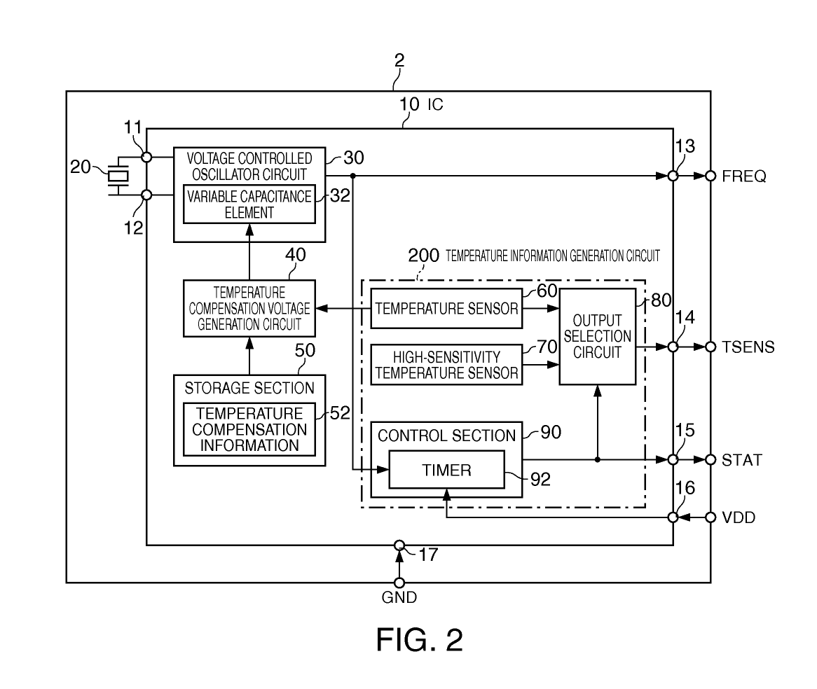

FIG. 2 is a diagram showing a configuration example of the oscillator 2 in the first embodiment. As shown in FIG. 2, the oscillator 2 in the first embodiment includes a quartz crystal resonator 20, and an IC 10 disposed adjacent to the quartz crystal resonator 20, and is configured as a temperature compensated Crystal oscillator (TCXO). The IC 10 has an external terminal 17 grounded via a GND terminal of the oscillator 2, and performs the oscillation operation using a power supply voltage supplied from an external terminal 16 via a VDD terminal of the oscillator 2. In this embodiment, the IC 10 is configured including a voltage controlled oscillator circuit 30, a temperature compensation voltage generation circuit 40, a storage section 50, a temperature sensor 60, a high-sensitivity temperature sensor 70, an output selection circuit 80, and a control section 90. The oscillator 2 in this embodiment can have a configuration obtained by eliminating or modifying some of the constituents (sections) shown in FIG. 2, or adding another constituent thereto.

The quartz crystal resonator 20 (an example of an oscillator element according to the invention) has an end connected to an external terminal 11 of the IC 10, and the other end connected to an external terminal 12 of the IC 10.

The voltage controlled oscillator circuit 30 is connected to the both ends of the quartz crystal resonator 20 via the external terminal 11 and the external terminal 12. The voltage controlled oscillator circuit 30 is provided with a variable capacitance element 32, and vibrates the quartz crystal resonator 20 at a frequency corresponding to the capacitance value of the variable capacitance element 32. The oscillation signal generated due to the oscillation of the quartz crystal resonator 20 is output to the outside from an external terminal 13 of the IC 10 via a FREQ terminal of the oscillator 2.

The temperature sensor 60 (an example of a first temperature detection section according to the invention) detects the internal temperature of the IC 10, and then outputs a detection signal (a detection voltage) corresponding to the temperature.

The temperature compensation voltage generation circuit 40 generates a temperature compensation voltage for performing the temperature compensation on the oscillation frequency of the quartz crystal resonator 20 in accordance with the detection signal of the temperature sensor 60 based on temperature compensation information 52 stored in the storage section 50. The temperature compensation information 52 can be the information (information such as coefficient values) of the function (e.g., a cubic function) for approximating the frequency-temperature characteristic of the quartz crystal resonator 20, or can be correspondence information between the temperature and the temperature compensation voltage for compensating the frequency-temperature characteristic of the quartz crystal resonator 20. The temperature compensation information 52 is obtained using a method such as least mean square approximation from the information of the oscillation frequency at a predetermined number of temperature points obtained in, for example, an inspection process of the oscillator 2, and is then written into the storage section 50.

The temperature compensation voltage generated by the temperature compensation voltage generation circuit 40 is applied to one end of the variable capacitance element 32 to thereby control the capacitance value of the variable capacitance element 32. Thus, the oscillation frequency of the quartz crystal resonator 20 is controlled to thereby perform the temperature compensation.

The high-sensitivity temperature sensor 70 (an example of a second temperature detection section according to the invention) detects the internal temperature of the IC 10, and then outputs a detection signal (a detection voltage) corresponding to the temperature. The high-sensitivity temperature sensor 70 has higher detection sensitivity than that of the temperature sensor 60.

The control section 90 is provided with a timer 92 for measuring the time (the elapsed time from startup) from when the external terminal 16 has been supplied with the power supply voltage using the oscillation signal generated due to the oscillation of the quartz crystal resonator 20, and generates a control signal (a selection signal) having a polarity switched (switched from a low level to a high level in this embodiment) when a predetermined period of time t elapses. The control signal (the selection signal) generated by the control section 90 is output to the outside from an external terminal 15 of the IC 10 via a STAT terminal of the oscillator 2.

The output selection circuit 80 exclusively selects and then outputs either one of the detection signal of the temperature sensor 60 and the detection signal of the high-sensitivity temperature sensor 70 in accordance with the control signal (the selection signal) of the control section 90. Specifically, the output selection circuit 80 selects the detection signal of the high-sensitivity temperature sensor 70 until a predetermined period of time t elapses from when the IC 10 is supplied with the power supply voltage, and then selects the detection signal of the temperature sensor 60 after the predetermined period of time t has elapsed. The output signal of the output selection circuit 80 is output to the outside from an external terminal 14 of the IC 10 via a TSENS terminal of the oscillator 2.

It should be noted that the circuit including the temperature sensor 60, the high-sensitivity temperature sensor 70, the output selection circuit 80, and the control section 90 corresponds to a temperature information generation circuit 200 according to the invention. Further, the output selection circuit 80 and the control section 90 correspond to the selection section according to the invention.

Going back to FIG. 1, the control device 3 of the embodiment is provided with a frequency conversion section 100, a control section 110, and a storage section 120, and can be, for example, a microcomputer. The control device 3 in this embodiment can have a configuration obtained by eliminating or modifying some of the constituents (sections) shown in FIG. 1, or adding another constituent thereto.

The frequency conversion section 100 performs the frequency conversion on the oscillation signal output from the FREQ terminal of the oscillator 2 at a conversion ratio corresponding to the control signal (the setting value) generated by the control section 110. The frequency conversion section 100 can be realized using, for example, a phase locked loop (PLL) synthesizer.

In this embodiment, the storage section 120 stores first temperature compensation information 122 and second temperature compensation information 124 in advance. The first temperature compensation information 122 is the information for performing further temperature compensation on the oscillation frequency of the oscillator 2 after the predetermined period of time t has elapsed from the time of startup of the oscillator 2, and can be, for example, correspondence information between the detection signal (the detection voltage) of the temperature sensor 60 included in the IC 10 of the oscillator 2 and the conversion ratio to be set to the frequency conversion section 100. The second temperature compensation information 124 is the information for performing temperature compensation on the oscillation frequency of the oscillator 2 before the predetermined period of time t elapses from the time of startup of the oscillator 2, and can be, for example, correspondence information between the detection signal (the detection voltage) of the high-sensitivity temperature sensor 70 included in the IC 10 of the oscillator 2 and the conversion ratio to be set to the frequency conversion section 100.

The control section 110 supplies the VDD terminal of the oscillator 2 with the power supply voltage, and at the same time generates the control signal for controlling the conversion ratio of the frequency conversion section 100 based on the detection signal output from the TSENS terminal of the oscillator 2 and the selection signal output from the STAT terminal. Specifically, if the STAT terminal is in the low level, the control section 110 calculates the conversion ratio corresponding to the detection signal (the detection signal of the high-sensitivity temperature sensor 70) output from the TSENS terminal using linear interpolation or the like based on the second temperature compensation information 124 stored in the storage section 120, and then generates the control signal for setting the conversion ratio to the frequency conversion section 100. Further, if the STAT terminal is in the high level, the control section 110 calculates the conversion ratio corresponding to the detection signal (the detection signal of the temperature sensor 60) output from the TSENS terminal using linear interpolation or the like based on the first temperature compensation information 122 stored in the storage section 120, and then generates the control signal for setting the conversion ratio to the frequency conversion section 100.

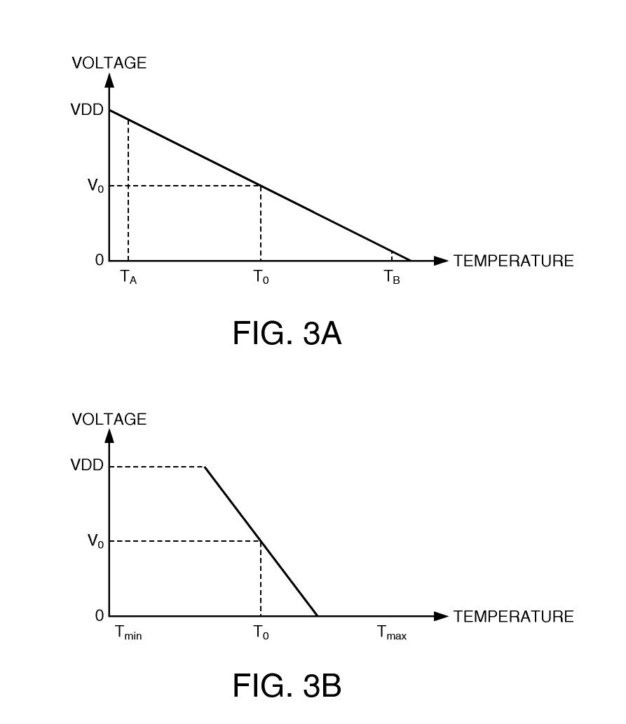

FIG. 3A is a diagram showing an example of the detection sensitivity of the temperature sensor 60, and FIG. 3B is a diagram showing an example of the detection sensitivity of the high-sensitivity temperature sensor 70. In FIGS. 3A and 3B, the horizontal axis represents temperature, and the vertical axis represents the detection voltage.

As shown in FIGS. 3A and 3B, in this embodiment, the temperature sensor 60 and the high-sensitivity temperature sensor 70 both have a property that the higher the temperature, the lower the detection voltage is.

The detection signal of the temperature sensor 60 is input to the temperature compensation voltage generation circuit 40, and is used for the temperature compensation in a desired temperature range (T_{A} through T_{B}) required. Therefore, as shown in FIG. 3A, since the temperature sensor 60 is required to vary the detection voltage in a predetermined voltage range included in a range from 0V through the power supply voltage VDD corresponding to the temperature range T_{A} through T_{B}, the detection sensitivity is lowered.

In contrast, the detection signal of the high-sensitivity temperature sensor 70 is used only at the time of startup of the oscillator 2, and therefore, it is sufficient for the high-sensitivity temperature sensor 70 to be able to detect a partial temperature range which is possible at the time of startup. Therefore, as shown in FIG. 3B, the high-sensitivity temperature sensor 70 is only required to vary the detection voltage in the range from 0V through the power supply voltage VDD corresponding to the partial temperature range centered on, for example, reference temperature T₀ (e.g., the inflection-point temperature of the frequency-temperature characteristic (the cubic function) of the quartz crystal resonator 20), and therefore, has higher sensitivity than that of the temperature sensor 60.

It should be noted that in the example shown in FIGS. 3A and 3B the detection voltage of the temperature sensor 60 and the detection voltage of the high-sensitivity temperature sensor 70 are both set to the voltage V₀ at the reference temperature T₀, but can be set to respective voltage values different from each other.

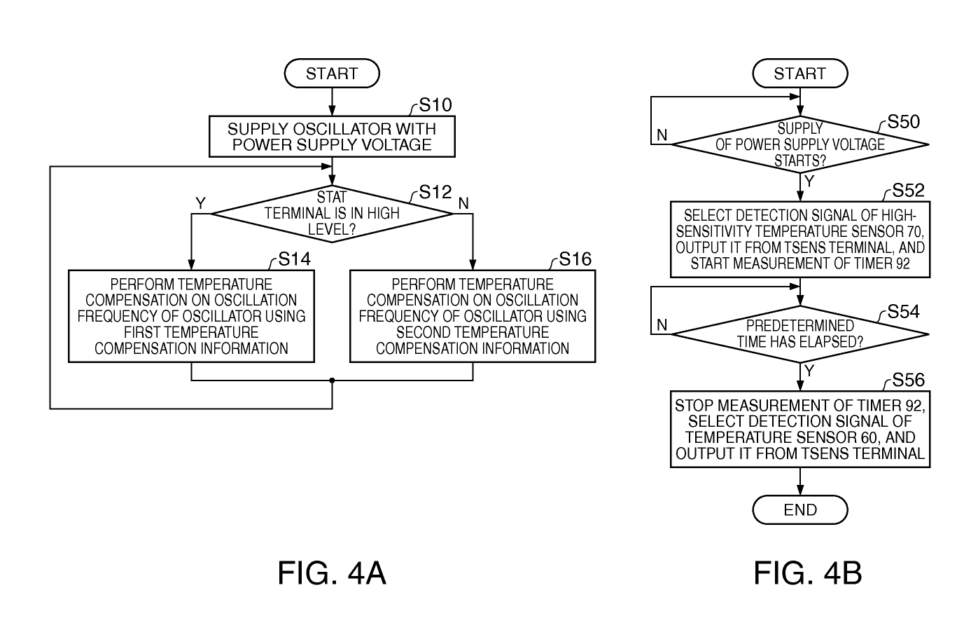

FIGS. 4A and 4B are diagrams showing an example of a flowchart of a temperature compensation process of the frequency temperature compensation system 1 according to the embodiment. FIG. 4A is a diagram showing an example of a flowchart of a process executed by the control section 110 of the control device 3, and FIG. 4B is a diagram showing an example of a flowchart of a process executed by the control section 90 of the IC 10 of the oscillator 2.

As shown in FIG. 4A, the control section 110 of the control device 3 supplies (S10) the oscillator 2 with the power supply voltage, and then monitors (S12) the voltage level of the STAT terminal of the oscillator 2. If the STAT terminal is in the high level (Y in S12), the control section 110 of the control device 3 performs the temperature compensation (S14) on the oscillation frequency of the oscillator 2 using the first temperature compensation information 122. In contrast, if the STAT terminal is in the low level (N in S12), the control section 110 of the control device 3 performs the temperature compensation (S16) on the oscillation frequency of the oscillator 2 using the second temperature compensation information 124. The control section 110 of the control device 3 performs the process on and after the step S12 repeatedly.

As shown in FIG. 4B, if the power supply voltage is supplied (Y in S50), the control section 90 of the IC 10 selects the detection signal of the high-sensitivity temperature sensor 70, then outputs the detection signal of the high-sensitivity temperature sensor 70 from the TSENS terminal, and then starts (S52) measurement of the timer 92.

Then, the control section 90 of the IC 10 determines (S54) whether or not the predetermined time t has elapsed based on the measurement value of the timer 92. Then, if the predetermined time t has elapsed (Y in S54), the control section 90 of the IC 10 stops the measurement of the timer 92, then selects the detection signal of the temperature sensor 60, then outputs (S56) the detection signal of the temperature sensor 60 from the TSENS terminal, and then terminates the process.

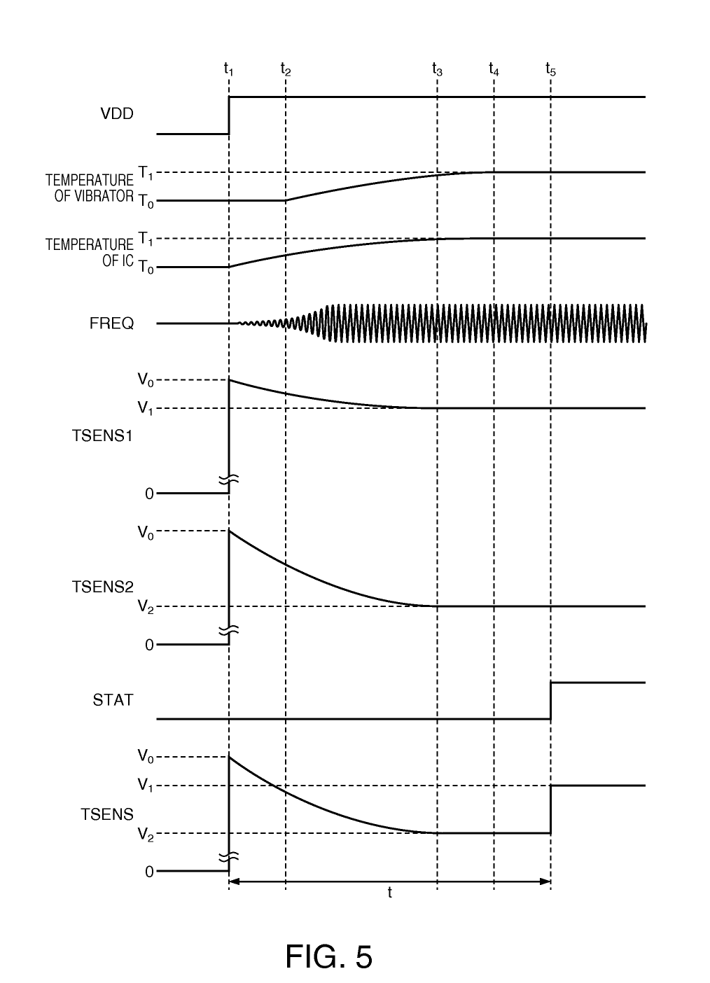

FIG. 5 is a diagram showing an example of signal waveforms of respective nodes of the oscillator 2. In the example of FIG. 5, it is assumed that the temperature sensor 60 and the high-sensitivity temperature sensor 70 have the sensitivity characteristics shown in FIGS. 3A and 3B, respectively, and there are shown the signal waveforms obtained in the case in which the power supply voltage is supplied in the state in which the internal temperature of the IC 10 is equal to the reference temperature T₀.

As shown in FIG. 5, in the case in which the VDD terminal is supplied with the power supply voltage at the time point t₁, the quartz crystal resonator 20 starts vibrating, and the oscillation signal is output from the FREQ terminal.

Further, in the case in which the VDD terminal is supplied with the power supply voltage, since the IC 10 generates heat, the internal temperature of the IC 10 gradually rises from T₀ to T₁ at time points t₁ through t₃. Due to the rise in the internal temperature of the IC 10, at the time points t₁ through t₃, the voltage of the output node TSENS1 of the temperature sensor 60 gradually drops from V₀ to V₁, and the voltage of the output node TSENS2 of the high-sensitivity temperature sensor 70 gradually drops from V₀ to V₂.

Although the temperature of the quartz crystal resonator 20 is kept at T₀ until the time point t₂, since the heat of the IC 10 is conducted to the quartz crystal resonator 20, the temperature of the quartz crystal resonator 20 gradually rises from T₀ to T₁ at the time points t₂ through t₄.

Until the time point t₅ at which the predetermined time t elapses from the time point t₀, the STAT terminal is kept in the low level, and the voltage of the TSENS terminal becomes equal to the voltage of the TSENS2 node. Since the STAT terminal is switched to the high level at the time point t₅, and is kept at the high level on and after the time point t₅, the voltage of the TSENS terminal becomes equal to the voltage of the TSENS1 node.

As is obvious from FIG. 5, the internal temperature of the IC 10 and the temperature of the quartz crystal resonator 20 are not equal to each other at the time points t₁ through t₄. As a result, at time points t₁ through t₄, an error is caused in the temperature compensation in the oscillator 2, and the frequency accuracy of the oscillation signal output from the FREQ terminal is transiently degraded.

Therefore, in this embodiment, the time sufficiently longer than the time (t₄−t₀) necessary for the temperature of the quartz crystal resonator 20 to be equal to the internal temperature of the IC 10 and then stabilized is set as the predetermined time t, and it is arranged that the oscillator 2 outputs the detection signal of the high-sensitivity temperature sensor 70 capable of detecting a small temperature variation until the predetermined time t elapses from the time of startup of the oscillator 2. Therefore, the control device 3 can accurately correct the temperature compensation error at the time of startup of the oscillator 2 by using the detection signal of the high-sensitivity temperature sensor 70.

Further, in this embodiment, since the internal temperature of the IC 10 and the temperature of the quartz crystal resonator 20 become equal to each other after the predetermined time t has elapsed from the time of startup of the oscillator 2, it is arranged that the oscillator 2 outputs the detection signal of the temperature sensor 60 capable of detecting a wide range of temperature although the sensitivity is low. Therefore, the control device 3 uses the detection signal of the temperature sensor 60 in the state in which the internal temperature of the IC 10 and the temperature of the quartz crystal resonator 20 are equal to each other, and thus, it is possible to perform accurate temperature compensation to the wide range of temperature variation.

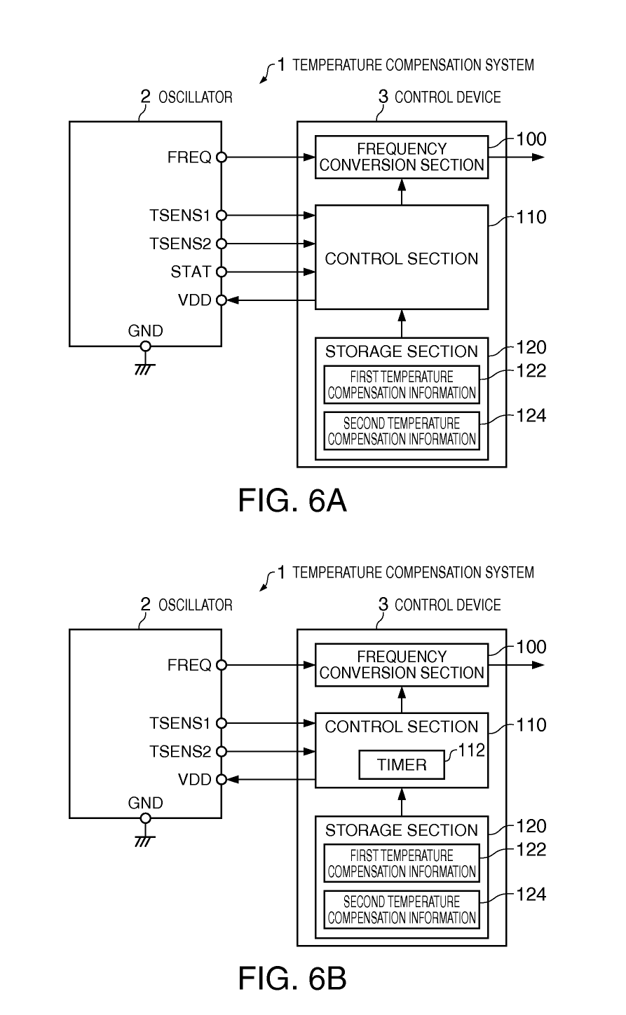

It should be noted that another configuration can be adopted as the configuration of the temperature compensation system 1 according to the embodiment. FIGS. 6A and 6B are diagrams each showing another configuration example of the frequency temperature compensation system according to the first embodiment. In FIGS. 6A and 6B, the same constituents as those shown in FIG. 1 are denoted with the same reference symbols, and the explanation thereof will be omitted.

In the example shown in FIG. 6A, the output selection circuit 80 of the IC 10 and the TSENS terminal are removed from the oscillator 2, and the TSENS1 terminal and the TSENS2 terminal are provided to the oscillator 2, and the detection signal of the temperature sensor 60 and the detection signal of the high-sensitivity temperature sensor 70 are externally output from the TSENS1 terminal and the TSENS2 terminal, respectively. Further, the control section 110 of the control device 3 selects either one of the detection signal output from the TSENS1 terminal and the detection signal output from the TSENS2 terminal in accordance with the voltage level of the STAT terminal to thereby control the conversion ratio of the frequency conversion section 100 as described above similarly to the output selection circuit 80 of the IC 10 shown in FIG. 2.

Further, in the example shown in FIG. 6B, the control section 90 and the output selection circuit 80 of the IC 10, the TSENS terminal, and the STAT terminal are removed from the oscillator 2, and the TSENS1 terminal and the TSENS2 terminal are provided to the oscillator 2, and the detection signal of the temperature sensor 60 and the detection signal of the high-sensitivity temperature sensor 70 are externally output from the TSENS1 terminal and the TSENS2 terminal, respectively. Further, the control section 110 of the control device 3 includes a timer 112, and measures the elapsed time from when the oscillator 2 is provided with the power supply voltage using the timer 112 similarly to the control section 90 of the IC 10 shown in FIG. 2. Then, the control section 110 of the control device 3 selects the detection signal output from the TSENS2 terminal until the predetermined time t elapses, selects the detection signal output from the TSENS1 terminal after the predetermined time t has elapsed to thereby control the conversion ratio of the frequency conversion section 100 as described above.

### 1-2. Second Embodiment

Since the overall configuration of a frequency temperature compensation system according to a second embodiment and the configuration of the control device 3 are substantially the same as those in the first embodiment (FIG. 1), the graphical description and the illustration thereof will be omitted.

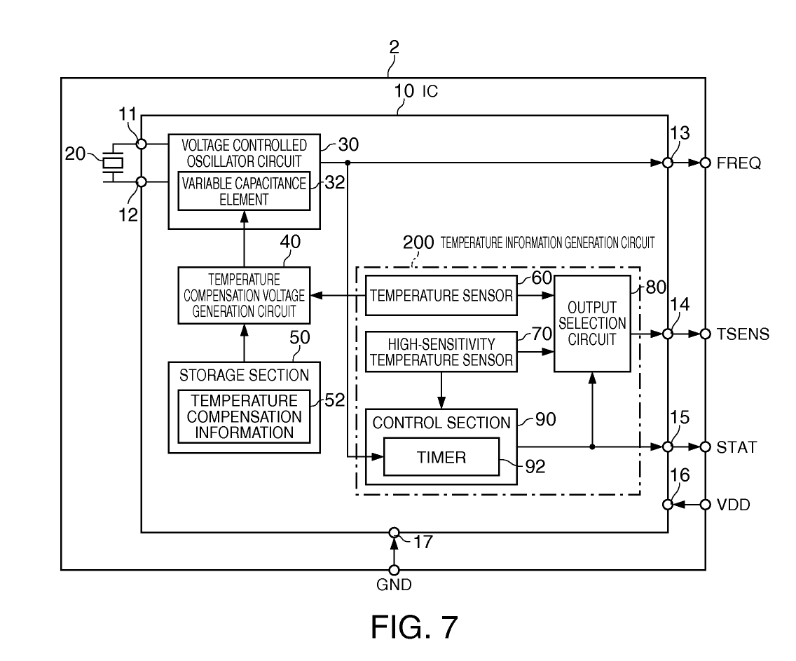

FIG. 7 is a diagram showing a configuration example of the oscillator 2 in the second embodiment. In FIG. 7, the same constituents as those shown in FIG. 2 are denoted with the same symbols. As shown in FIG. 7, similarly to the first embodiment, the oscillator 2 in the second embodiment includes the quartz crystal resonator 20, and the IC 10, and is configured as a temperature compensated Crystal oscillator (TCXO). In this embodiment, the IC 10 is configured including the voltage controlled oscillator circuit 30, the temperature compensation voltage generation circuit 40, the storage section 50, the temperature sensor 60, the high-sensitivity temperature sensor 70, the output selection circuit 80, and the control section 90 similarly to the first embodiment. Since the functions of the respective constituents except the control section 90 are the same as those in the first embodiment, the explanation thereof will be omitted.

In this embodiment, the control section 90 is provided with the timer 92 for measuring the time using the oscillation signal generated due to the oscillation of the quartz crystal resonator 20, and generates a control signal (a selection signal) having a polarity switched (switched from the low level to the high level in this embodiment) in the case in which the variation of the detection voltage value of the high-sensitivity temperature sensor 70 falls within a predetermined range continuously for a predetermined period of time t after the power supply voltage is supplied (after startup). The control signal (the selection signal) generated by the control section 90 is output to the outside from the external terminal 15 of the IC 10 via the STAT terminal of the oscillator 2.

The output selection circuit 80 selects the detection signal of the high-sensitivity temperature sensor 70 until the variation of the detection voltage value of the high-sensitivity temperature sensor 70 falls within the predetermined range continuously for the predetermined time t after startup, and then selects the detection signal of the temperature sensor 60 after the variation thereof falls within the predetermined range continuously for the predetermined time t in accordance with the control signal (the selection signal).

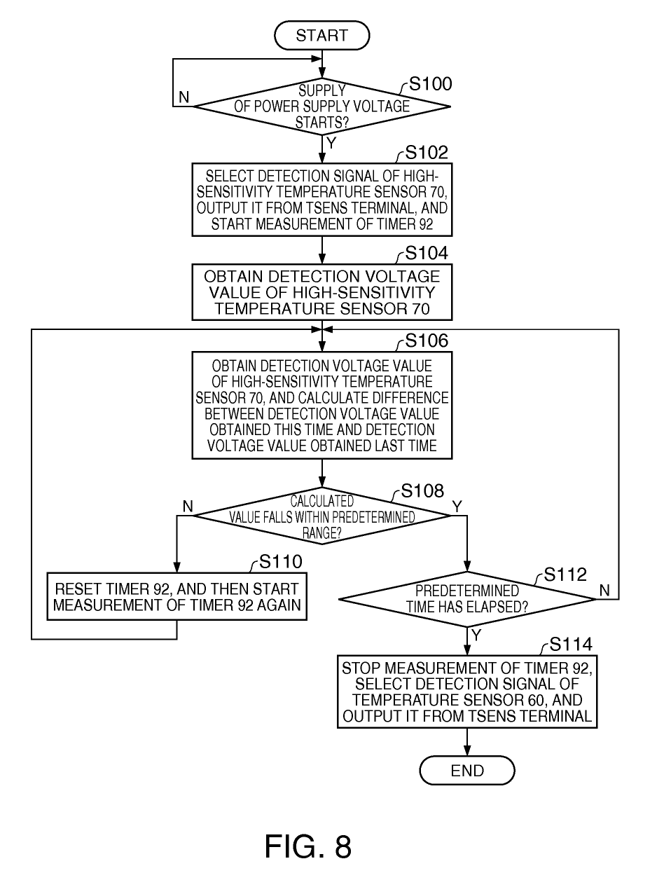

FIG. 8 is a diagram showing an example of a flowchart of a process executed by the control section 90 of the IC 10 of the oscillator 2 in this embodiment. It should be noted that since the flowchart of the process executed by the control section 110 of the control device 3 in this embodiment is substantially the same as shown in FIG. 4A, the graphical description and the illustration thereof will be omitted.

As shown in FIG. 8, if the power supply voltage is supplied (Y in S100), the control section 90 of the IC 10 selects the detection signal of the high-sensitivity temperature sensor 70, then outputs the detection signal of the high-sensitivity temperature sensor 70 from the TSENS terminal, and then starts (S102) measurement of the timer 92.

Then, the control section 90 of the IC 10 obtains (S104) the detection voltage value of the high-sensitivity temperature sensor 70.

Then, the control section 90 of the IC 10 obtains the detection voltage value of the high-sensitivity temperature sensor 70 again, and then calculates (S106) the difference (the variation) between the detection voltage value obtained this time and the detection voltage value obtained last time.

Then, the control section 90 of the IC 10 determines (S108) whether or not the calculated value (the difference (the variation) between the detection voltage value obtained this time and the detection voltage value obtained last time) in the step S106 falls within the predetermined range. Although it is ideally sufficient to determine whether or not the difference (the variation) between the detection voltage value obtained this time and the detection voltage value obtained last time is 0, the control section 90 of the IC 10 actually determines whether or not the difference (the variation) between the detection voltage value obtained this time and the detection voltage value obtained last time falls within a predetermined range taking the noise superimposed on the detection signal of the high-sensitivity temperature sensor 70 into consideration.

If the calculated value in the step S106 is not within the predetermined range, the control section 90 of the IC 10 resets the timer 92, and then starts (S110) the measurement of the timer 92 again, and then performs the process on and after the step S106 again.

In contrast, if the calculated value in the step S106 falls within the predetermined range, the control section 90 of the IC 10 determines (S112) whether or not the predetermined time t has elapsed based on the measurement value of the timer 92. Then, if the predetermined time t has not elapsed (N in S112), the control section 90 of the IC 10 performs the process on and after the step S106 again, and if the predetermined time t has elapsed (Y in S112), the control section 90 stops the measurement of the timer 92, then selects the detection signal of the temperature sensor 60 to be output (S114) from the TSENS terminal, and then terminates the process.

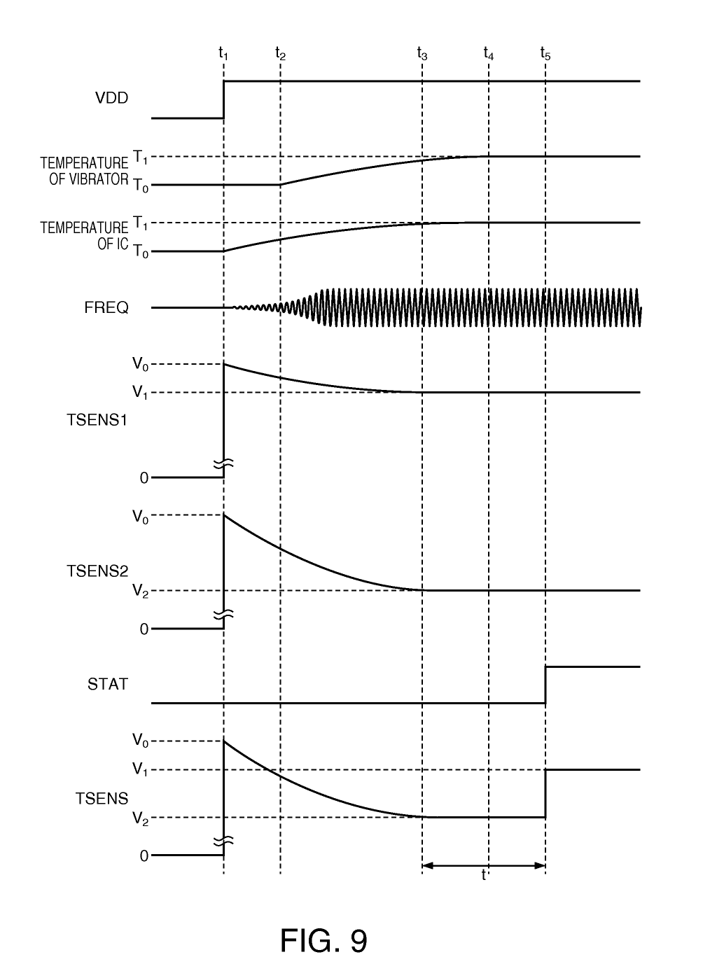

FIG. 9 is a diagram showing an example of signal waveforms of the respective nodes of the oscillator 2. In the example of FIG. 9, it is assumed that the temperature sensor 60 and the high-sensitivity temperature sensor 70 have the sensitivity characteristics shown in FIGS. 3A and 3B, respectively, and there are shown the signal waveforms obtained in the case in which the power supply voltage is supplied in the state in which the internal temperature of the IC 10 is equal to the reference temperature T₀.

As shown in FIG. 9, in the case in which the VDD terminal is supplied with the power supply voltage at the time point t₁, the quartz crystal resonator 20 starts vibrating, and the oscillation signal is output from the FREQ terminal.

Further, in the case in which the VDD terminal is supplied with the power supply voltage, since the IC 10 generates heat, the internal temperature of the IC 10 gradually rises from T₀ to T₁ at time points t₁ through t₃. Due to the rise in the internal temperature of the IC 10, at the time points t₁ through t₃, the voltage of the output node TSENS1 of the temperature sensor 60 gradually drops from V₀ to V′, and the voltage of the output node TSENS2 of the high-sensitivity temperature sensor 70 gradually drops from V₀ to V₂.

Although the temperature of the quartz crystal resonator 20 is kept at T₀ until the time point t₂, since the heat of the IC 10 is conducted to the quartz crystal resonator 20, the temperature of the quartz crystal resonator 20 gradually rises from T₀ to T₁ at the time points t₂ through t₄.

At the time points t₁ through t₃, since the detection voltage (the voltage at the TSENS2 node) of the high-sensitivity temperature sensor 70 gradually drops, the timer 92 repeats a reset operation. Then, since the detection voltage of the high-sensitivity temperature sensor 70 is stable (roughly constant) on and after the time point t₃, no reset operation is caused in the timer 92, and the STAT terminal is switched from the low level to the high level at the time point t₅ when the predetermined time t has elapsed from the time point t₃. Therefore, in the period from the time point t₀ to the time point t₅, since the STAT terminal is kept in the low level, the voltage of the TSENS terminal is equal to the voltage of the TSENS2 node. Further, on and after the time point t₅, since the STAT terminal is kept in the high level, the voltage of the TSENS terminal is equal to the voltage of the TSENS1 node.

In this embodiment, the time sufficiently longer than the time (t₄−t₃) necessary for the temperature of the quartz crystal resonator 20 to be equal to the internal temperature of the IC 10 and then stabilized is set as the predetermined time t, and it is arranged that the oscillator outputs the detection signal of the high-sensitivity temperature sensor 70 capable of detecting a small temperature variation until the variation of the detection voltage of the high-sensitivity temperature sensor 70 falls within the predetermined range continuously for a period equal to or longer than the time t after startup of the oscillator 2. Therefore, the control device 3 can accurately correct the temperature compensation error at the time of startup of the oscillator 2 by using the detection signal of the high-sensitivity temperature sensor 70.

Further, in this embodiment, since the internal temperature of the IC 10 and the temperature of the quartz crystal resonator 20 are equal to each other if the variation of the detection voltage of the high-sensitivity temperature sensor 70 falls within the predetermined range continuously for the period equal to or longer than the predetermined time t, it is arranged that the oscillator 2 outputs the detection signal of the temperature sensor 60 capable of detecting a wide range of temperature although the sensitivity is low. Therefore, the control device 3 uses the detection signal of the temperature sensor 60 in the state in which the internal temperature of the IC 10 and the temperature of the quartz crystal resonator 20 are equal to each other, and thus, it is possible to perform accurate temperature compensation to the wide range of temperature variation.

It should be noted that although in this embodiment, the output signal of the output selection circuit 80 is switched based on the determination on whether or not the variation of the detection voltage of the high-sensitivity temperature sensor 70 falls within the predetermined range continuously for the predetermined time after startup of the oscillator 2, it is also possible to switch the output signal of the output selection circuit 80 based on the determination on whether or not the variation of the detection voltage of the temperature sensor 60 falls within a predetermined range continuously for a predetermined period of time. It should be noted that since the variation of the detection voltage of the high-sensitivity temperature sensor 70 is greater than the variation of the detection voltage of the temperature sensor 60, the output signal of the output selection circuit 80 can be switched at more appropriate timing by determining whether or not the variation of the detection voltage of the high-sensitivity temperature sensor 70 falls within the predetermined range continuously for the predetermined period.

It should be noted that another configuration can also be adopted as the configuration of the temperature compensation system 1 according to this embodiment, and for example, such configurations as shown in FIGS. 6A and 6B can be adopted.

### 1-3. Third Embodiment

Since the overall configuration of a frequency temperature compensation system according to a third embodiment and the configuration of the control device 3 are substantially the same as those in the first embodiment (FIG. 1) and the second embodiment, the graphical description and the illustration thereof will be omitted.

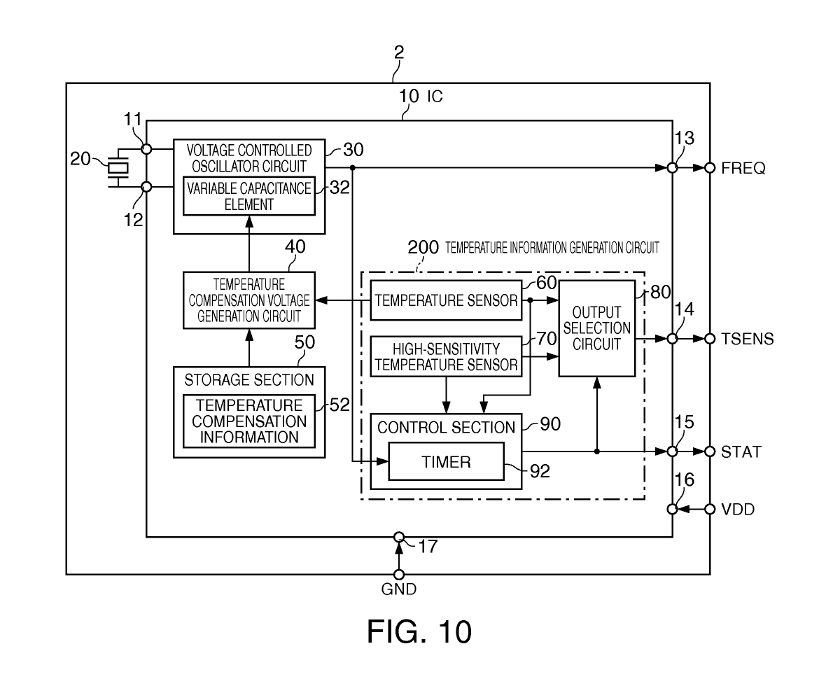

FIG. 10 is a diagram showing a configuration example of the oscillator 2 in the third embodiment. In FIG. 10, the same constituents as those shown in FIG. 2 are denoted with the same symbols. As shown in FIG. 10, similarly to the first embodiment and the second embodiment, the oscillator 2 in the third embodiment includes the quartz crystal resonator 20, and the IC 10, and is configured as a temperature compensated Crystal oscillator (TCXO). In this embodiment, the IC 10 is configured including the voltage controlled oscillator circuit 30, the temperature compensation voltage generation circuit 40, the storage section 50, the temperature sensor 60, the high-sensitivity temperature sensor 70, the output selection circuit 80, and the control section 90 similarly to the first embodiment. Since the functions of the respective constituents except the control section 90 are the same as those in the first embodiment and the second embodiment, the explanation thereof will be omitted.

In this embodiment, the control section 90 is provided with the timer 92 for measuring the time using the oscillation signal generated due to the oscillation of the quartz crystal resonator 20, and generates a control signal (a selection signal) having a polarity switched (switched from the low level to the high level in this embodiment) in the case in which a variation of a difference between the detection voltage value of the temperature sensor 60 and the detection voltage value of the high-sensitivity temperature sensor 70 falls within a predetermined range continuously for a predetermined period of time t after the power supply voltage is supplied (after startup). The control signal (the selection signal) generated by the control section 90 is output to the outside from the external terminal 15 of the IC 10 via the STAT terminal of the oscillator 2. Further, the output selection circuit 80 selects the detection signal of the high-sensitivity temperature sensor 70 until the variation of the difference between the detection voltage value of the temperature sensor 60 and the detection voltage value of the high-sensitivity temperature sensor 70 falls within the predetermined range continuously for the predetermined time t after startup, and then selects the detection signal of the temperature sensor 60 after the variation thereof falls within the predetermined range continuously for the predetermined time t in accordance with the control signal (the selection signal).

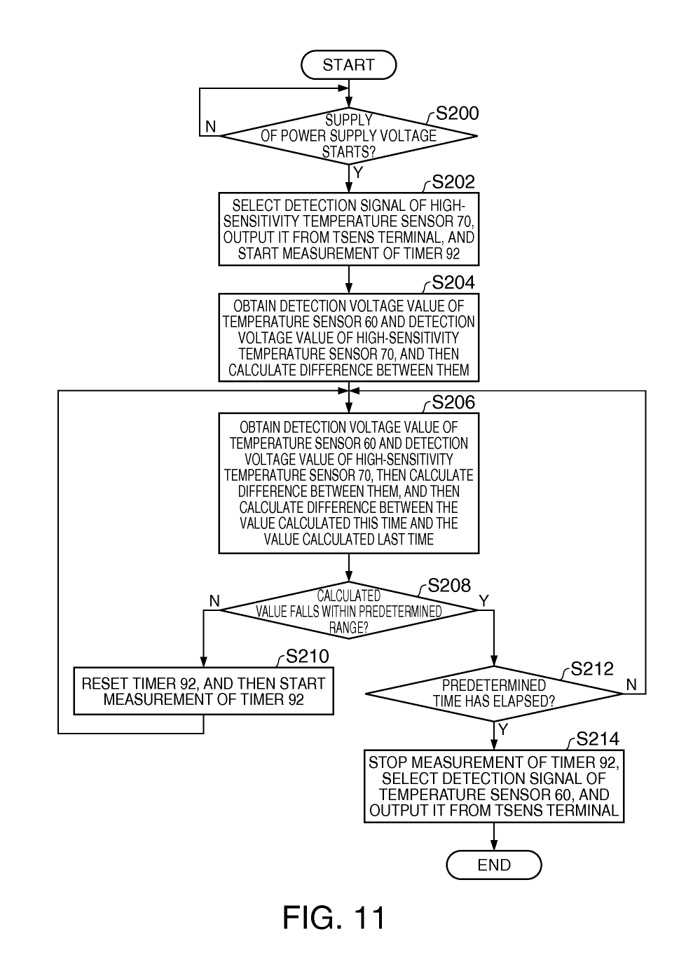

FIG. 11 is a diagram showing an example of a flowchart of a process executed by the control section 90 of the IC 10 of the oscillator 2 in this embodiment. It should be noted that since the flowchart of the process executed by the control section 110 of the control device 3 in this embodiment is substantially the same as shown in FIG. 4A, the graphical description and the illustration thereof will be omitted.

As shown in FIG. 11, if the power supply voltage is supplied (Y in S200), the control section 90 of the IC 10 selects the detection signal of the high-sensitivity temperature sensor 70, then outputs the detection signal of the high-sensitivity temperature sensor 70 from the TSENS terminal, and then starts (S202) measurement of the timer 92.

Then, the control section 90 of the IC 10 obtains the detection voltage value of the temperature sensor 60 and the detection voltage value of the high-sensitivity temperature sensor 70, and then calculates (S204) the difference therebetween.

Then, the control section 90 of the IC 10 obtains the detection voltage value of the temperature sensor 60 and the detection voltage value of the high-sensitivity temperature sensor 70, then calculates the difference therebetween again, and then calculates (S206) the difference (the variation) between the calculated value obtained this time and the calculated value obtained last time.

Then, the control section 90 of the IC 10 determines (S208) whether or not the calculated value (the difference (the variation) between the calculated value obtained this time and the calculated value obtained last time) in the step S206 falls within the predetermined range. Although it is ideally sufficient to determine whether or not the difference (the variation) between the calculated value obtained this time and the calculated value obtained last time is 0, the control section 90 of the IC 10 actually determines whether or not the difference (the variation) between the calculated value obtained this time and the calculated value obtained last time falls within the predetermined range taking the noise superimposed on the detection signal of the temperature sensor 60 and the noise superimposed on the detection signal of the high-sensitivity temperature sensor 70 into consideration.

If the calculated value in the step S206 is not within the predetermined range, the control section 90 of the IC 10 resets the timer 92, and then starts (S210) the measurement of the timer 92 again, and then performs the process on and after the step S206 again.

In contrast, if the calculated value in the step S206 falls within the predetermined range, the control section 90 of the IC 10 determines (S212) whether or not the predetermined time t has elapsed based on the measurement value of the timer 92. Then, if the predetermined time t has not elapsed (N in S212), the control section 90 of the IC 10 performs the process on and after the step S206 again, and if the predetermined time t has elapsed (Y in S212), the control section 90 stops the measurement of the timer 92, then selects the detection signal of the temperature sensor 60 to be output (S214) from the TSENS terminal, and then terminates the process.

In the nodes of the oscillator 2 in this embodiment, for example, the signal waveforms substantially the same as those shown in FIG. 9 are generated, respectively. At the time points t₁ through t₃, since the detection voltage (the voltage at the TSENS1 node) of the temperature sensor 60 and the detection voltage (the voltage at the TSENS2 node) of the high-sensitivity temperature sensor 70 gradually drop, and the difference therebetween gradually increases, the timer 92 repeats a reset operation. Then, since the detection voltage of the temperature sensor 60 and the detection voltage of the high-sensitivity temperature sensor 70 are stable, and the difference therebetween is roughly constant on and after the time point t₃, no reset operation is caused in the timer 92, and the STAT terminal is switched from the low level to the high level at the time point t₅ when the predetermined time t has elapsed from the time point t₃. Therefore, in the period from the time point t₀ to the time point t₅, since the STAT terminal is kept in the low level, the voltage of the TSENS terminal is equal to the voltage of the TSENS2 node. Further, on and after the time point t₅, since the STAT terminal is kept in the high level, the voltage of the TSENS terminal is equal to the voltage of the TSENS1 node.

In this embodiment, similarly to the second embodiment, the time sufficiently longer than the time (t₄−t₃) necessary for the temperature of the quartz crystal resonator 20 to be equal to the internal temperature of the IC 10 and then stabilized is set as the predetermined time t, and it is arranged that the oscillator 2 outputs the detection signal of the high-sensitivity temperature sensor 70 capable of detecting a small temperature variation until the variation of the difference between the detection voltage of the temperature sensor 60 and the detection voltage of the high-sensitivity temperature sensor 70 falls within the predetermined range continuously for a period equal to or longer than the predetermined time t after startup of the oscillator 2. Therefore, the control device 3 can accurately correct the temperature compensation error at the time of startup of the oscillator 2 by using the detection signal of the high-sensitivity temperature sensor 70.

Further, in this embodiment, similarly to the second embodiment, since the internal temperature of the IC 10 and the temperature of the quartz crystal resonator 20 are equal to each other if the variation of the difference between the detection voltage of the temperature sensor 60 and the detection voltage of the high-sensitivity temperature sensor 70 falls within the predetermined range continuously for the period equal to or longer than the predetermined time t, it is arranged that the oscillator 2 outputs the detection signal of the temperature sensor 60 capable of detecting a wide range of temperature although the sensitivity is low. Therefore, the control device 3 uses the detection signal of the temperature sensor 60 in the state in which the internal temperature of the IC 10 and the temperature of the quartz crystal resonator 20 are equal to each other, and thus, it is possible to perform accurate temperature compensation to the wide range of temperature variation.

It should be noted that another configuration can also be adopted as the configuration of the temperature compensation system 1 according to this embodiment, and for example, such configurations as shown in FIGS. 6A and 6B can be adopted.

### 1-4. Fourth Embodiment

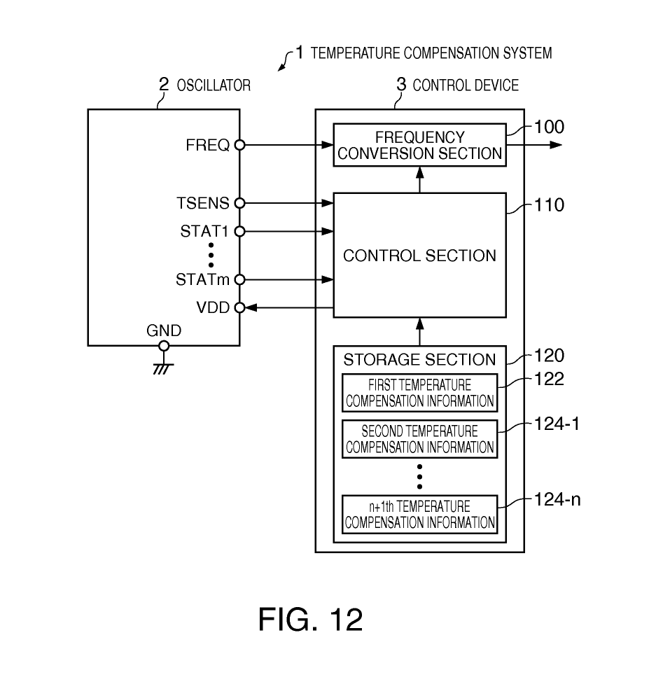

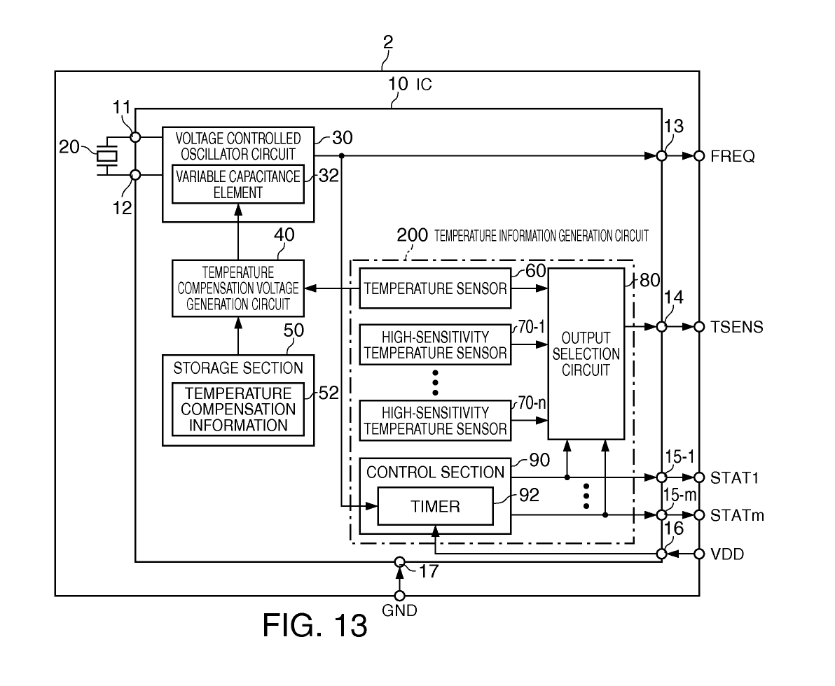

FIG. 12 is a diagram showing a configuration example of a frequency temperature compensation system according to a fourth embodiment. In FIG. 12, the same constituents as those shown in FIG. 1 are denoted with the same symbols. Further, FIG. 13 is a diagram showing a configuration example of the oscillator 2 in the fourth embodiment. In FIG. 13, the same constituents as those shown in FIG. 2 are denoted with the same symbols.

As shown in FIG. 13, similarly to the first embodiment, the oscillator 2 in the fourth embodiment includes the quartz crystal resonator 20, and the IC 10, and is configured as a temperature compensated Crystal oscillator (TCXO). In this embodiment, the IC 10 is configured including the voltage controlled oscillator circuit 30, the temperature compensation voltage generation circuit 40, the storage section 50, the temperature sensor 60, n high-sensitivity temperature sensors 70-1 through 70-n, the output selection circuit 80, and the control section 90. The oscillator 2 in this embodiment can have a configuration obtained by eliminating or modifying some of the constituents (sections) shown in FIG. 13, or adding another constituent thereto.

The respective functions of the voltage controlled oscillator circuit 30, the temperature compensation voltage generation circuit 40, the storage section 50, and the temperature sensor 60 are substantially the same as those of the first embodiment, and therefore, the explanation thereof will be omitted.

The n high-sensitivity temperature sensors 70-1 through 70-n (an example of a plurality of second temperature detection sections according to the invention) each detect the internal temperature of the IC 10, and then output a detection signal (a detection voltage) corresponding to the temperature, but are different from each other in detectable temperature range. The n high-sensitivity temperature sensors 70-1 through 70-n each have higher detection sensitivity than that of the temperature sensor 60. The n high-sensitivity temperature sensors 70-1 through 70-n can have the same detection sensitivity, or can be different from each other in detection sensitivity.

The control section 90 is provided with the timer 92 for measuring the time (the elapsed time from startup) from when the external terminal 16 has been supplied with the power supply voltage using the oscillation signal generated due to the oscillation of the quartz crystal resonator 20, and generates an m-bit control signal (a selection signal) composed of bits each representing a value determined in accordance with the detection voltage value of the temperature sensor 60 before the predetermined period of time t elapses, and each representing a predetermined value (all of the bits are set to the high level in this embodiment) when the predetermined time t has elapsed. The symbol m is an integer fulfilling 2m-1<n+1≦2m. The m-bit control signal (the selection signal) generated by the control section 90 is output to the outside from m external terminals 15-1 through 15-m of the IC 10 via m external terminals STAT1 through STATm of the oscillator 2.

The output selection circuit 80 exclusively selects and then outputs either one of the detection signal of the temperature sensor 60 and the detection signals of the n high-sensitivity temperature sensors 70-1 through 70-n in accordance with the m-bit control signal (the selection signal) from the control section 90. For example, in the case of n=3 (the case in which the IC 10 includes three high-sensitivity temperature sensors 70-1 through 70-3), m=2 is obtained, and the output selection circuit 80 exclusively selects and then outputs one of the four detection signals, namely the detection signal of the temperature sensor 60 and the detection signals of the high-sensitivity temperature sensors 70-1 through 70-3, in accordance with the 2-bit control signal.

Specifically, the output selection circuit 80 selects the detection signal of one of the high-sensitivity temperature sensors 70-1 through 70-n, which can appropriately detect the internal temperature of the IC 10, in accordance with the m-bit control signal (the selection signal) until a predetermined period of time t elapses from when the IC 10 is supplied with the power supply voltage, and then selects the detection signal of the temperature sensor 60 after the predetermined period of time t has elapsed. The output signal of the output selection circuit 80 is output to the outside from the external terminal 14 of the IC 10 via the TSENS terminal of the oscillator 2.

As shown in FIG. 12, the control device 3 of this embodiment is provided with the frequency conversion section 100, the control section 110, and the storage section 120, and can be, for example, a microcomputer. The control device 3 in this embodiment can have a configuration obtained by eliminating or modifying some of the constituents (sections) shown in FIG. 12, or adding another constituent thereto.

The function of the frequency conversion section 100 is substantially the same as that in the first embodiment, and therefore, the explanation thereof will be omitted.

In this embodiment, the storage section 120 stores first temperature compensation information 122 and second through n+1-th temperature compensation information 124-1 through 124-n in advance. The first temperature compensation information 122 is substantially the same as that in the first embodiment, and therefore, the explanation thereof will be omitted. The second through n+1-th temperature compensation information 124-1 through 124-n are each the information for performing the temperature compensation on the oscillation frequency of the oscillator 2 until the predetermined period of time t elapses from the time of startup of the oscillator using the detection signals of the high-sensitivity temperature sensors 70-1 through 70-n, respectively, included in the IC 10 of the oscillator 2. For example, the second through n+1-th temperature compensation information 124-1 through 124-n each can be the correspondence information between the detection signals (the detection voltages) of the respective high-sensitivity temperature sensors 70-1 through 70-n and the conversion ratios to be set to the frequency conversion section 100.

The control section 110 supplies the VDD terminal of the oscillator 2 with the power supply voltage, and at the same time generates the control signal for controlling the conversion ratio of the frequency conversion section 100 based on the detection signal output from the TSENS terminal of the oscillator 2 and the m-bit selection signal output from the STAT1 through STATm terminals. Specifically, if at least one of the STAT1 through STATm terminals is in the low level, the control section 110 selects either one of the second through n+1-th temperature compensation information 124-1 through 124-n stored in the storage section 120 in accordance with the value, then calculates the conversion ratio corresponding to the detection signal (the detection signal corresponding one of the high-sensitivity temperature sensors 70-1 through 70-n) output from the TSENS terminal using linear interpolation or the like based on the temperature compensation information thus selected, and then generates the control signal for setting the conversion ratio to the frequency conversion section 100. Further, if all of the STAT1 through STATm terminals are in the high level, the control section 110 calculates the conversion ratio corresponding to the detection signal (the detection signal of the temperature sensor 60) output from the TSENS terminal using linear interpolation or the like based on the first temperature compensation information 122 stored in the storage section 120, and then generates the control signal for setting the conversion ratio to the frequency conversion section 100.

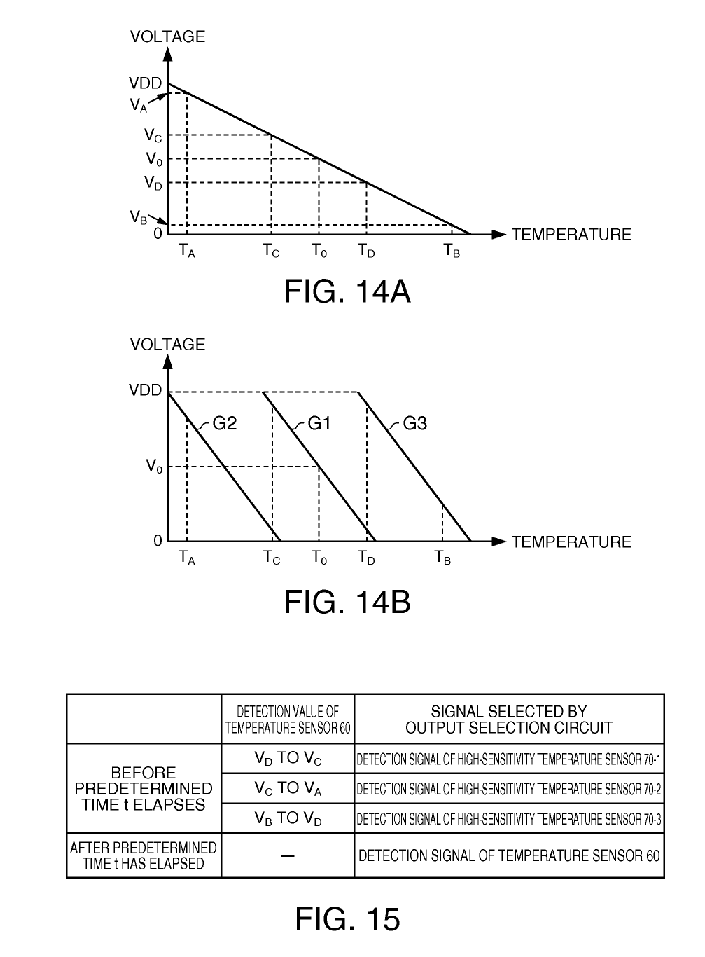

FIG. 14A is a diagram showing an example of the detection sensitivity of the temperature sensor 60, and FIG. 14B is a diagram showing an example of the detection sensitivity of the three high-sensitivity temperature sensors 70-1 through 70-3 in the case of n=3. In FIGS. 14A and 14B, the horizontal axis represents temperature, and the vertical axis represents the detection voltage. Further, in FIG. 14B, G1, G2, and G3 represent the detection sensitivity of the high-sensitivity temperature sensor 70-1, the detection sensitivity of the high-sensitivity temperature sensor 70-2, and the detection sensitivity of the high-sensitivity temperature sensor 70-3, respectively.

As shown in FIGS. 14A and 14B, in this embodiment, the temperature sensor 60 and the high-sensitivity temperature sensors 70-1 through 70-3 all have a property that the higher the temperature, the lower the detection voltage is.

As shown in FIG. 14A, the temperature sensor 60 varies the detection voltage in a predetermined voltage range included in a range from 0V through the power supply voltage VDD corresponding to the desired temperature range T_{A} through T_{B} required.

As shown in FIG. 14B, the temperature range which can be detected by the high-sensitivity temperature sensor 70-1 and the temperature range which can be detected by the high-sensitivity temperature sensor 70-2 overlap each other around temperature T_{C}. Similarly, the temperature range which can be detected by the high-sensitivity temperature sensor 70-1 and the temperature range which can be detected by the high-sensitivity temperature sensor 70-3 overlap each other around temperature T_{D}.

It should be noted that in the example shown in FIGS. 14A and 14B the detection voltage of the temperature sensor and the detection voltage of the high-sensitivity temperature sensor 70-1 are both set to the voltage V₀ at the reference temperature T₀, but can be set to respective voltage values different from each other.

FIG. 15 is a diagram showing an example of the selection logic of the detection signal performed by the output selection circuit 80 in the case in which the temperature sensor 60 has the detection sensitivity shown in FIG. 14A, and the three high-sensitivity temperature sensors 70-1 through 70-3 have the detection sensitivity shown in FIG. 14B.

In the example shown in FIG. 15, until the predetermined period of time t elapses from the time of startup of the oscillator 2, the control section 90 of the IC 10 generates the 2-bit control signal (e.g., the control signal with the 2 bits of “00”) for selecting the detection signal of the high-sensitivity temperature sensor 70-1 if the internal temperature of the IC 10 is in a range from T_{C} to T_{D}, namely if the detection voltage value of the temperature sensor 60 is in a range from V_{D} to V_{C}.

Further, until the predetermined period of time t elapses from the time of startup of the oscillator 2, the control section 90 of the IC 10 generates the 2-bit control signal (e.g., the control signal with the 2 bits of “01”) for selecting the detection signal of the high-sensitivity temperature sensor 70-2 if the internal temperature of the IC 10 is in a range from T_{A} to T_{C}, namely if the detection voltage value of the temperature sensor 60 is in a range from V_{C} to V_{A}.

Further, until the predetermined period of time t elapses from the time of startup of the oscillator 2, the control section 90 of the IC 10 generates the 2-bit control signal (e.g., the control signal with the 2 bits of “10”) for selecting the detection signal of the high-sensitivity temperature sensor 70-3 if the internal temperature of the IC 10 is in a range from T_{D} to T_{B}, namely if the detection voltage value of the temperature sensor 60 is in a range from V_{B} to V_{D}.

Further, after the predetermined period of time t has elapsed from the time of startup of the oscillator 2, the control section 90 of the IC 10 generates the 2-bit control signal (e.g., the control signal with the 2 bits of “11”) for selecting the detection signal of the temperature sensor 60 independently of the internal temperature of the IC 10.

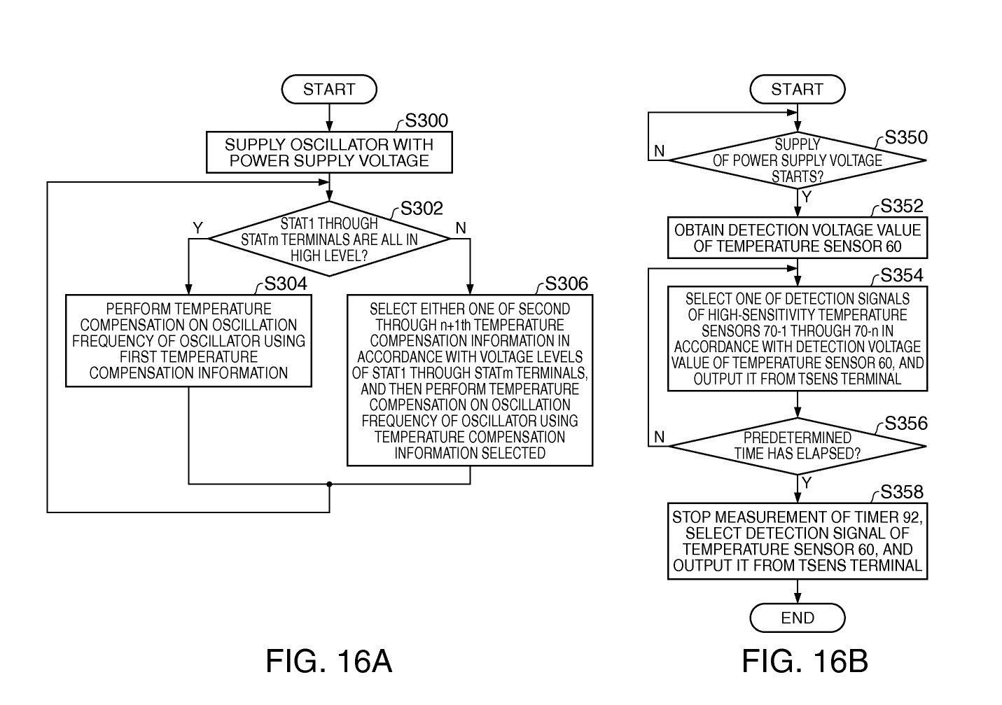

FIGS. 16A and 16B are diagrams showing an example of a flowchart of a temperature compensation process of the frequency temperature compensation system 1 according to this embodiment. FIG. 16A is a diagram showing an example of a flowchart of a process executed by the control section 110 of the control device 3, and FIG. 16B is a diagram showing an example of a flowchart of a process executed by the control section 90 of the IC 10 of the oscillator 2.

As shown in FIG. 16A, the control section 110 of the control device 3 supplies (S300) the oscillator 2 with the power supply voltage, and then monitors (S302) the voltage level of the STAT1 through STATm terminals of the oscillator 2. If the STAT1 through STATm terminals are all in the high level (Y in S302), the control section 110 of the control device 3 performs the temperature compensation (S304) on the oscillation frequency of the oscillator 2 using the first temperature compensation information 122. In contrast, if at least one of the STAT1 through STATm terminals is in the low level (N in S302), the control section 110 of the control device 3 selects either one of the second through n+1-th temperature compensation information 124-1 through 124-n in accordance with the voltage levels of the STAT1 through STATm terminals, and then performs the temperature compensation on the oscillation frequency of the oscillator 2 using the temperature compensation information thus selected. The control section 110 of the control device 3 performs the process on and after the step S302 repeatedly.

As shown in FIG. 16B, if the power supply voltage is supplied (Y in S350), the control section 90 of the IC 10 selects the detection signal of the temperature sensor 60, then outputs the detection signal of the temperature sensor 60 from the TSENS terminal, and then starts (S352) measurement of the timer 92.

Then, the control section 90 of the IC 10 obtains (S352) the detection voltage value of the temperature sensor 60.

Then, the control section 90 of the IC 10 selects either one of the detection signals of the high-sensitivity temperature sensors 70-1 through 70-n in accordance with the detection voltage value of the temperature sensor 60 obtained in the step S352, and then output (S354) the detection signal thus selected from the TSENS terminal.

Then, the control section 90 of the IC 10 determines (S356) whether or not the predetermined time t has elapsed based on the measurement value of the timer 92. The control section 90 of the IC 10 performs the process of the step S354 repeatedly until the predetermined time t has elapsed (N in S356), and if the predetermined time t has elapsed (Y in S356), the control section 90 stops the measurement of the timer 92, then selects the detection signal of the temperature sensor 60 to be output (S358) from the TSENS terminal, and then terminates the process.

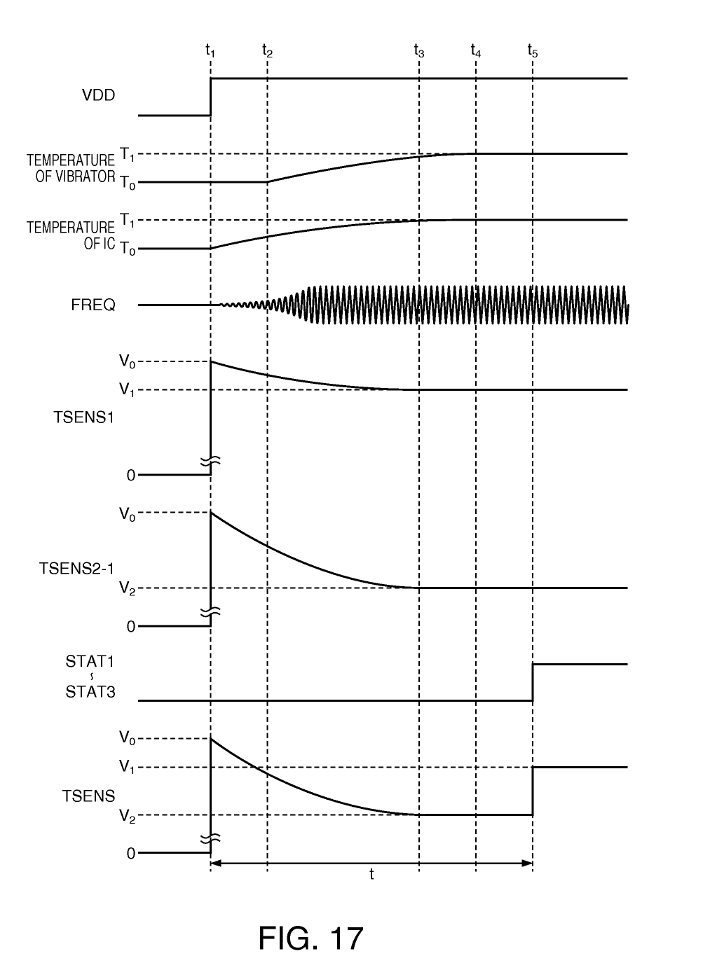

FIG. 17 is a diagram showing an example of signal waveforms of the respective nodes of the oscillator 2. In the example shown in FIG. 17, it is assumed that the temperature sensor 60 has the detection sensitivity shown in FIG. 14A, and the three high-sensitivity temperature sensors 70-1 through 70-3 have the detection sensitivity shown in FIG. 14B, there are shown the signal waveforms in the case in which the power supply voltage is applied in the state in which the internal temperature of the IC 10 is equal to the reference temperature T₀.

As shown in FIG. 17, in the case in which the VDD terminal is supplied with the power supply voltage at the time point t₁, the quartz crystal resonator 20 starts vibrating, and the oscillation signal is output from the FREQ terminal.

Further, in the case in which the VDD terminal is supplied with the power supply voltage, since the IC 10 generates heat, the internal temperature of the IC 10 gradually rises from T₀ to T₁ at time points t₁ through t₃. Due to the rise in the internal temperature of the IC 10, at the time points t₁ through t₃, the voltage of the output node TSENS1 of the temperature sensor 60 gradually drops from V₀ to V₁, and the voltage of the output node TSENS2-1 of the high-sensitivity temperature sensor 70-1 gradually drops from V₀ to V₂.

Although the temperature of the quartz crystal resonator 20 is kept at T₀ until the time point t₂, since the heat of the IC 10 is conducted to the quartz crystal resonator 20, the temperature of the quartz crystal resonator 20 gradually rises from T₀ to T₁ at the time points t₂ through t₄.

Until the time point t₅ at which the predetermined time t elapses from the time point t₀, the STAT1 through STAT3 terminals are all kept in the low level, and the voltage of the TSENS terminal becomes equal to the voltage of the TSENS2-1 node. Since the STAT1 through STAT3 terminals are switched to the high level at the time point t₅, and are kept at the high level on and after the time point t₅, the voltage of the TSENS terminal becomes equal to the voltage of the TSENS1 node.

In this embodiment, the time sufficiently longer than the time (t₄−t₀) necessary for the temperature of the quartz crystal resonator 20 to be equal to the internal temperature of the IC 10 and then stabilized is set as the predetermined time t, and it is arranged that the oscillator selects the detection signal of the high-sensitivity temperature sensor, which can appropriately detect the internal temperature of the IC 10, out of the detection signals of the high-sensitivity temperature sensors 70-1 through 70-3, which are capable of detecting the small temperature variation, and then outputs the detection signal thus selected until the predetermined time t elapses from the time of startup of the oscillator 2. Therefore, the control device 3 uses the detection signal of the high-sensitivity temperature sensor appropriately selected in accordance with the internal temperature of the IC 10 at the time of startup of the oscillator 2, and can therefore accurately correct the temperature compensation error at the time of startup of the oscillator 2.

Further, in this embodiment, since the internal temperature of the IC 10 and the temperature of the quartz crystal resonator 20 become equal to each other after the predetermined time t has elapsed from the time of startup of the oscillator 2, it is arranged that the oscillator 2 outputs the detection signal of the temperature sensor 60 capable of detecting a wide range of temperature although the sensitivity is low. Therefore, the control device 3 uses the detection signal of the temperature sensor 60 in the state in which the internal temperature of the IC 10 and the temperature of the quartz crystal resonator 20 are equal to each other, and thus, it is possible to perform accurate temperature compensation to the wide range of temperature variation.

It should be noted that another configuration can also be adopted as the configuration of the temperature compensation system 1 according to this embodiment, and for example, such configurations as shown in FIGS. 6A and 6B can be adopted.

### 2. Electronic Apparatus

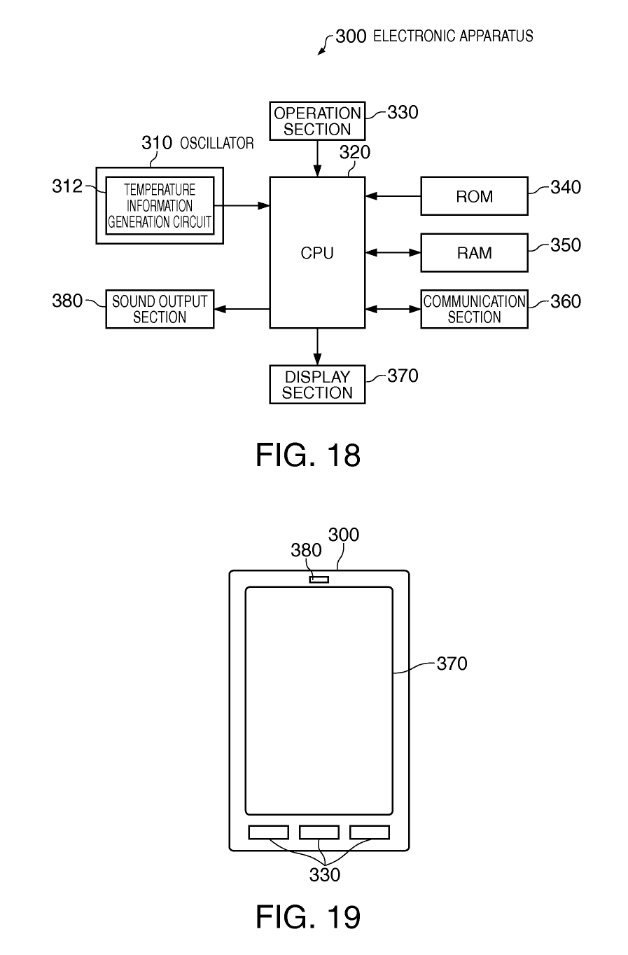

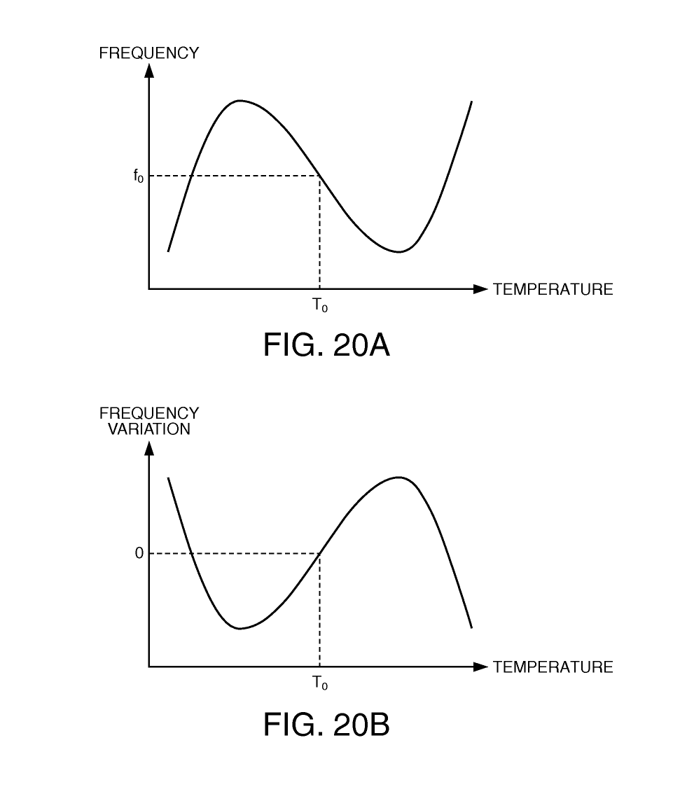

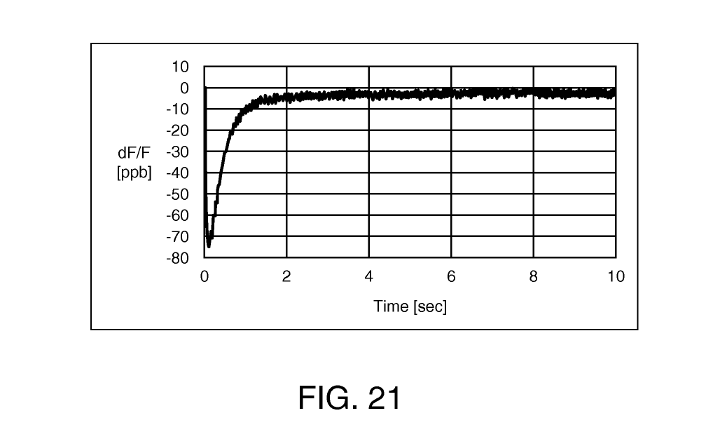

FIG. 18 is a functional block diagram of an electronic apparatus according to this embodiment. Further, FIG. 19 is a diagram showing an example of the appearance of a smartphone as an example of the electronic apparatus according to this embodiment.

The electronic apparatus 300 according to this embodiment is configured including an oscillator 310, a central processing unit (CPU) 320, an operation section 330, a read only memory (ROM) 340, a random access memory (RAM) 350, a communication section 360, a display section 370, and a sound output section 380. It should be noted that the electronic apparatus according to this embodiment can have a configuration obtained by eliminating or modifying some of the constituents (sections) shown in FIG. 18, or adding another constituent thereto.

The oscillator 310 includes a temperature information generation circuit 312, and outputs an oscillation signal (a clock signal) and temperature information. The oscillator 310 is, for example, the oscillator 2 in either one of the first through fourth embodiments described above, and the temperature information generation circuit 312 is, for example, the temperature information generation circuit 200 in either one of the first through fourth embodiments described above.

The CPU 320 performs a variety of arithmetic processing and control processing using the oscillation signal (the clock signal) output by the oscillator 310 in accordance with the program stored in the ROM 340 and so on. Specifically, the CPU 320 performs a variety of processes corresponding to the operation signal from the operation section 330, a process of controlling the communication section 360 for performing data communication with external devices, a process of transmitting a display signal for making the display section 370 display a variety of types of information, a process of making the sound output section 380 output a variety of sounds, and so on. Further, the CPU 320 performs a process (a process substantially the same as that of the control device 3 in the first through fourth embodiments described above) of performing the temperature compensation on the oscillator 310.

The operation section 330 is an input device including operation keys, button switches, and so on, and outputs the operation signal corresponding to the operation by the user to the CPU 320.

The ROM 340 stores a program, data, and so on for the CPU 320 to perform a variety of arithmetic processes and control processes.

The RAM 350 is used as a working area of the CPU 320, and temporarily stores, for example, the program and data retrieved from the ROM 340, the data input from the operation section 330, and the calculation result obtained by the CPU 320 performing operations with the various programs.

The communication section 360 performs a variety of control processes for achieving the data communication between the CPU 320 and the external devices.

The display section 370 is a display device formed of a liquid crystal display (LCD) or the like, and displays a variety of information based on a display signal input from the CPU 320.

The sound output section 380 is a device for outputting sounds such as a speaker.

By installing the oscillator 2 according to this embodiment as the oscillator 310, the electronic apparatus having higher performance can be realized. For example, it is possible to realize the electronic apparatus provided with a GPS receiver, and capable of performing a positioning calculation and so on using the output data of the GPS receiver immediately after startup.

As the electronic apparatus 300, a variety of electronic apparatuses can be adopted, and there can be cited, for example, a device of a base station for cellular phones, a GPS receiver, a personal computer (e.g., a mobile type personal computer, a laptop personal computer, and a tablet personal computer), a mobile terminal such as a cellular phone, a digital still camera, an inkjet ejection device (e.g., an inkjet printer), a storage area network apparatus such as a router and a switch, a local area network apparatus, a television set, a video camera, a video cassette recorder, a car navigation system, a pager, a personal digital assistance (including one having a communication function), an electronic dictionary, an electronic calculator, an electronic game machine, a gaming controller, a word processor, a workstation, a picture phone, a security television monitor, an electronic binoculars, a POS terminal, a medical instrument (e.g., an electronic thermometer, a blood pressure monitor, a blood glucose monitor, an electrocardiograph, ultrasonic diagnostic equipment, and an electronic endoscope), a fish finder, a variety of measuring instruments (e.g., a reference signal source for a spectrum analyzer), gauges (e.g., gauges for cars, aircrafts, and boats and ships), a flight simulator, a head-mount display, a motion tracer, a motion tracker, a motion controller, and a pedestrian dead reckoning (PDR) system.

### 3. Modified Example

The invention is not limited to the embodiments described above, but can be put into practice with various modifications within the scope or the spirit of the invention.

Although in this embodiments, the explanation is presented citing the temperature compensated Crystal oscillator (TCXO) as an example of the oscillator 2, the oscillator according to the invention is not limited thereto, but any oscillator outputting the temperature information can be adopted. The oscillator according to the invention can be, for example, a piezoelectric oscillator, an SAW oscillator, a voltage controlled oscillator, a silicon oscillator, an atomic oscillator, and so on each provided with a temperature compensation function, or can be, for example, a crystal oscillator (a Temperature Sensing Crystal Oscillator (TSXO)), which incorporates an internal ROM storing a correspondence table between temperature information and an oscillation frequency together with a temperature sensor, and does not perform the temperature compensation.

Further, although in this embodiments the quartz crystal resonator is used as the oscillator element of the oscillator 2, there can be used as the oscillator element, for example, a surface acoustic wave (SAW) resonator, an AT-cut quartz crystal resonator, an SC-cut quartz crystal resonator, a tuning-fork quartz crystal resonator, other piezoelectric vibrators, and a micro electromechanical system (MEMS) vibrator. Further, as the base material of the oscillator element, there can be used, for example, a piezoelectric single crystal such as a quartz crystal, lithium tantalate, or lithium niobate, a piezoelectric material such as piezoelectric ceramics including, for example, lead zirconate titanate, or a silicon semiconductor material. Further, as the excitation device of the oscillator element, there can be used a device using a piezoelectric effect, or electrostatic drive using a coulomb force.

Further, although in this embodiments, the explanation is presented citing the oscillator as an example of the electronic component in the temperature compensation system and the temperature compensation method according to the invention, any electronic component subject to the temperature compensation can be adopted as the electronic component according to the invention, and a variety of types of sensors such as a gyro sensor can also be adopted.

Further, although in this embodiments there is adopted the configuration using the temperature information generation circuit 200 as a part of the single chip IC 10, it is not required for the temperature information generation circuit according to the invention to be formed of the single chip IC. For example, it is also possible to configure the temperature information generation circuit 200 so that a part of the temperature information generation circuit 200 is included in an electronic component such as an oscillator, and the rest thereof is included in the control device.

Further, although in this embodiments the semiconductor temperature sensor 60 included in the IC 10 is used as the first temperature detection section according to the invention, it is possible to use a thermistor instead of the temperature sensor 60. Similarly, although in this embodiments the semiconductor high-sensitivity temperature sensor 70 included in the IC 10 is used as the second temperature detection section according to the invention, it is possible to use a thermistor, which has higher sensitivity than that of the thermistor as the first temperature detection section, instead of the high-sensitivity temperature sensor 70.

Further, in the second and third embodiments, it is possible to arrange that the IC 10 includes the plurality of high-sensitivity temperature sensors 70-1 through 70-n described in the fourth embodiment. In these cases, it is also possible to arrange that one of the detection signals of the high-sensitivity temperature sensors 70-1 through 70-n is selected in accordance with the detection voltage value of the temperature sensor 60, and then the process of the steps S104 and S106 shown in FIG. 8, or the process of the steps S204 and S206 shown in FIG. 11 is performed using the detection signal thus selected similarly to the process of the step S354 shown in FIG. 16B.

The embodiments and the modified examples described above are illustrative only, and the invention is not limited thereto. For example, it is also possible to arbitrarily combine the embodiments and the modified examples described above with each other.

The invention includes configurations (e.g., configurations having the same function, the same way, and the same result, or configurations having the same object and the same advantages) substantially the same as the configuration described as the embodiments of the invention. Further, the invention includes configurations obtained by replacing a non-essential part of the configuration described as the embodiments of the invention. Further, the invention includes configurations exerting the same functional effects and configurations capable of achieving the same object as the configuration described as the embodiments of the invention. Further, the invention includes configurations obtained by adding technologies known to the public to the configuration described as the embodiments of the invention.

The entire disclosure of Japanese Patent Application No. 2012-116898, filed May 22, 2012 is expressly incorporated by reference herein.

What is claimed is:

1. A temperature information generation circuit comprising:
a first temperature detection section;
one or plural second temperature detection sections having detection sensitivity higher than detection sensitivity of the first temperature detection section; and
a selection section adapted to select a detection signal of the one or plural second temperature detection sections upon supply of a power supply voltage, and then selecting a detection signal of the first temperature detection section at a predetermined timing.

2. The temperature information generation circuit according to claim 1, wherein
the selection section selects the detection signal of the one or plural second temperature detection sections until a predetermined time elapses from the supply of the power supply voltage, and selects the detection signal of the first temperature detection section after the predetermined time has elapsed.

3. The temperature information generation circuit according to claim 1, wherein
the selection section selects the detection signal of the one or plural second temperature detection sections until a variation of the detection signal of the one or plural second temperature detection sections falls within a predetermined range continuously for a predetermined time after the supply of the power supply voltage, and selects the detection signal of the first temperature detection section in a case in which the variation of the detection signal of the one or plural second temperature detection sections falls within the predetermined range continuously for the predetermined time.

4. The temperature information generation circuit according to claim 1, wherein
the selection section selects the detection signal of the one or plural second temperature detection sections until a variation of a difference between the detection signal of the first temperature detection section and the detection signal of the one or plural second temperature detection sections falls within a predetermined range continuously for a predetermined time after the supply of the power supply voltage, and selects the detection signal of the first temperature detection section in a case in which the variation of the difference between the detection signal of the first temperature detection section and the detection signal of the one or plural second temperature detection sections falls within the predetermined range continuously for the predetermined time.

5. The temperature information generation circuit according to claim 1, wherein
the plural second temperature detection sections have respective detectable temperature ranges different from each other.

6. The temperature information generation circuit according to claim 5, wherein
the selection section selects one of the detection signals of the plural second temperature detection sections in accordance with the detection signal of the first temperature detection section after supplying the power supply voltage and before selecting the detection signal of the first temperature detection section.

7. An oscillator comprising:
the temperature information generation circuit according to claim 1; and
an oscillator element.

8. An electronic apparatus comprising:
the temperature information generation circuit according to claim 1.

9. A temperature compensation system comprising:
an electronic component; and
a control device,
wherein the electronic component includes
a first temperature detection section, and
one or plural second temperature detection sections having detection sensitivity higher than detection sensitivity of the first temperature detection section, and
the control device performs temperature compensation of the electronic component based on a detection signal of the one or plural second temperature detection sections in a period from when supplying the electronic component with a power supply voltage to a predetermined timing, and performs temperature compensation of the electronic component based on a detection signal of the first temperature detection section after the predetermined timing.

10. A temperature compensation method of an electronic component, comprising:
performing, by a control device, temperature compensation of the electronic component based on a detection signal of one or plural second temperature detection sections having detection sensitivity higher than detection sensitivity of a first temperature detection section included in the electronic component in a period from when supplying the electronic component with a power supply voltage to a predetermined timing; and
performing, by the control device, the temperature compensation of the electronic component based on a detection signal of the first temperature detection section included in the electronic component after the predetermined timing.
